(19) United States
(12) Patent Application Publication
(10) Pub. No.: US 2012/0119384 A1
(43) Pub. Date: May 17, 2012

(54) SEMICONDUCTOR DEVICE AND MANUFACTURING METHOD THEREOF

(75) Inventors: Yoshimasa Takii, Osaka (JP); Takayuki Kai, Kyoto (JP); Daishiro Saito, Toyama (JP); Takafumi Okuma, Osaka (JP)

(73) Assignee: PANASONIC CORPORATION, Osaka (JP)

(21) Appl. No.: 13/387,204

(22) PCT Filed: Mar. 28, 2011
(86) PCT No.: PCT/JP2011/001825

§ 371 Date: Jan. 26, 2012

(30) Foreign Application Priority Data
May 31, 2010 (JP) 2010-124013

(51) Int. Cl. H01L 23/48; H01L 21/768

(52) U.S. Cl. 257/774; 438/667; 257/E23.011; 257/E21.586

(57) ABSTRACT

In a semiconductor device having a through-hole electrode and a manufacturing method thereof, a dummy groove hole portion for forming insulating portion insulating wirings from each other is provided, to surround a rewiring layer including a through-hole electrode on a back surface of a semiconductor substrate. This allows the wirings to be insulated from each other just by removing the metal layer existing at a bottom portion of the dummy groove hole portion. Thus, a reduction in the processing time can be realized.

### TECHNICAL FIELD

The present invention relates to a semiconductor device and a manufacturing method thereof. In particular, the present invention relates to a semiconductor device having a through-hole electrode and a manufacturing method thereof.

### BACKGROUND ART

In recent years, as a three-dimensional packaging technology and a novel packaging technology, a CSP (Chip Size Package) has been receiving attention. The CSP refers to a small package having an outer dimension which is substantially identical to the outer dimension of the semiconductor chip.

Conventionally, as one type of the CSP, a BGA-type semiconductor device having a through-hole electrode is known. The BGA-type semiconductor device has a through-hole electrode that penetrates through the semiconductor substrate and is connected to a pad electrode. Further, the semiconductor device is provided with, on its back surface, a grid-like array of a plurality of ball-like conductive terminals each made of a metal member such as a solder.

In integrating such a semiconductor device into electronic equiμment, the conductive terminals are connected to a wiring pattern on the circuit board (e.g., a printed circuit board).

As compared to other CSP-type semiconductor devices such as an SOP (Small Outline Package) or a QFP (Quad Flat Package) having lead pins projecting sideways, such a BOA-type semiconductor device can be provided with many conductive terminals. In addition thereto, such a BGA-type semiconductor device is advantageous in its being capable of achieving miniaturization, as compared to other CSP-type semiconductor devices.

Next, a description will be given, with reference to FIG. 7 which is a flowchart showing an overview of a manufacturing method of a BOA-type semiconductor device having a through-hole electrode according to Conventional Example 1 disclosed in PATENT LITERATURE 1, and with reference to FIGS. 8A to 8K which are cross-sectional views at respective steps.

First, as shown in FIG. 8A, on the front surface (the bottom surface in FIG. 8A) of a silicon semiconductor substrate 55 where an electronic device 52 and a pad electrode 53 are formed, a support member 54 is bonded, having a first insulating film 51 and a resin-made adhesion layer interposed therebetween (step S101). The electronic device 52 may be a light receiving element such as a COD, an infrared sensor or the like, or a light emitting element, or the like. The pad electrode 53 is an external connection-purpose electrode connected to the electronic device 52.

Next, as shown in FIG. 83, on the back surface (the top surface in FIG. 8A) of the semiconductor substrate 55, a resist via pattern layer 56 is formed (step S102).

Next, as shown in FIG. 5C, using the resist via pattern layer 56 as a mask, a hole electrode hole 57 extending from the back surface of the semiconductor substrate 55 to reach the pad electrode 53 is formed by dry etching (step S103). At the bottom portion of the via hole 57, the first insulating film 51 is exposed. Subsequently, using the resist layer 56 used in performing dry etching to the via hole 57 as a mask, the first insulating film 51 at the bottom portion of the via hole 57 is removed by dry etching. Thus, the pad electrode 53 is partially exposed at the bottom portion of the via hole 57. Thereafter, the resist layer 56 is removed from the back surface of the semiconductor substrate 55.

Next, as shown in FIG. 8D, on the semiconductor substrate 55 including the inside of the via hole 57, a second insulating film 58 is formed (step S104). Here, the second insulating film 58 at the bottom portion of the via hole 57 is formed to be thinner than the second insulating film 58 on the front surface of the semiconductor substrate 55, in accordance with the depth of the via hole 57.

Next, as shown in FIG. 8E, by performing anisotropic dry etching to the semiconductor substrate 55 where the second insulating film 58 is formed, the second insulating film 58 is etched (step S105). This etching removes the second insulating film 58 at the bottom portion of the via hole 57, whereby the pad electrode 53 is partially exposed. However, on the front surface of the semiconductor substrate 55 and on the sidewall of the via hole 57, the second insulating film 58 remains.

Next, as shown in FIG. 8F, on the second insulating film 58 inside the via hole 57 and on the front surface of the semiconductor substrate 55, a barrier metal layer 59 is formed (step S106). Subsequently, on the barrier metal layer 59 inside the via hole 57 and on the front surface of the semiconductor substrate 55, a seed metal layer 60 is formed (step S107). The seed metal layer 60 functions as an electrode for forming a wiring formation layer 61, whose description will be given later, by plating.

Next, as shown in FIG. 8G, a wiring formation layer 61 is formed so as to cover the barrier metal layer 59 and the seed metal layer 60 formed on the front surface of the semiconductor substrate 55 (step S112).

Then, a second resist layer 62 is formed at a prescribed region on the wiring formation layer 61 (step S113).

Next, as shown in FIG. 8H, using the second resist layer 62 as a mask, by performing patterning to the wiring formation layer 61, a through-hole electrode 49 and a wiring layer 48 continuous to the through-hole electrode 49 are formed (step S114). It is to be noted that, the prescribed region where the second resist layer 62 is to be formed is a formation region of the via hole 57, and is a region on the front surface of the semiconductor substrate 55 where a wiring layer having prescribed pattern, whose description will be given later, is to be formed.

Here, the through-hole electrode 49 is formed by being electrically connected to the pad electrode 53 exposed at the bottom portion of the via hole 57, having the seed metal layer 60 and the barrier metal layer 59 interposed therebetween. Further, the wiring layer 48 (the wiring formation layer 61) which is continuous to the through-hole electrode 49 to be electrically connected thereto is formed to have a prescribed pattern on the front surface of the semiconductor substrate 55 having the seed metal layer 60 and the barrier metal layer 59 interposed therebetween.

Subsequently, as shown in FIG. 8I, using the second resist layer 62 as a mask, the seed metal layer 60 and the barrier metal layer 59 are removed by patterning (step S114).

Next, as shown in FIG. 8J, the second resist layer 62 is removed (step S110).

Next, as shown in FIG. 8K, on the front surface of the semiconductor substrate 55 including the inside of the via hole 57, that is, on the second insulating film 58, and on the through-hole electrode 49 and the wiring layer 48, a protection layer 63 is formed so as to cover them (step S111). The protection layer 63 is made of, e.g., a resist material or the like. In the protection layer 63, at the position corresponding to the wiring layer 48, an opening 63a is provided. Then, on the wiring layer 48 exposed at the opening 63a, a ball-like conductive terminal 64 made of metal, e.g., solder or the like, is formed.

Next, along a not-shown dicing line, the semiconductor substrate 55 is subjected to dicing. Thus, a plurality of semiconductor devices each being a semiconductor chip having the through-hole electrode 49 is completed.

FIGS. 9A and 9B each show one example of a part of the semiconductor device prepared in accordance with the manufacturing method described in the foregoing. FIGS. 9A and 9B show two through-hole electrodes 49 and the wiring layer 48 connecting between the through-hole electrodes 49, in a state before the protection film 63 is formed. FIG. 9A shows a cross-sectional structure of the through-hole electrode 49. FIG. 9B schematically shows the structure of the two through-hole electrodes 49 and the wiring layer 48 connecting between the through-hole electrodes 49 as seen from above. FIG. 9B shows the two through-hole electrodes and the wiring connecting between the through-hole electrodes, and the second insulating film 58 intended to insulate them from the surrounding.

Next, a description will be given of an overview of a manufacturing method of the BGA-type semiconductor device having a through-hole electrode according to Conventional Example 2 disclosed in PATENT LITERATURE 2. The description will be given with reference to FIG. 10 which is a flowchart of the semiconductor device manufacturing method of Conventional Example 2, and with reference to FIGS. 11A to 11K which are cross-sectional views at respective steps.

The method of Conventional Example 2 is referred to as the semi-additive process. The method of Conventional Example 2 is identical to the semiconductor device manufacturing method of PATENT LITERATURE 1 up to the forming of the barrier metal layer 59 and that of the seed metal layer 60 as shown in FIGS. 11A to 11F. Therefore, the description thereof is not repeated, and a description will mainly be given of different steps.

First, as shown in FIG. 11G, a second resist layer 62 is formed at a prescribed region on the barrier metal layer 59 and the seed metal layer 60 (step S108). Here, the prescribed region where the second resist layer 62 is to be formed is a region except for the formation region for the via hole 57, and a region on the front surface of the semiconductor substrate 55 where the wiring layer 48 having a prescribed pattern, whose description will be given later, is not formed.

Next, as shown in FIG. 11H, using the second resist layer 62 as a mask, a wiring formation layer 61 is formed (step S109).

Next, as shown in FIG. 11I, the second resist layer 62 is removed (step S110).

Next, as shown in FIG. 11J, using the wiring formation layer 61 as a mask, the seed metal layer 60 and the barrier metal layer 59 are removed (step S115).

Next, as shown in FIG. 11K, on the front surface of the semiconductor substrate 55 including the inside of the via hole 57, that is, on the second insulating film 58, and on the through-hole electrode 49 and the wiring layer 48, a protection layer 63 is formed so as to cover them (step S111). The protection layer 63 is made of, e.g., a resist material or the like. In the protection layer 63, at the position corresponding to the wiring layer 48, an opening 63a is provided. Then, on the wiring layer 61 exposed at the opening 63a, a ball-like conductive terminal 64 made of metal, e.g., solder or the like, is formed.

Next, along a not-shown dicing line, the semiconductor substrate 55 is subjected to dicing. Thus, a plurality of semiconductor devices each being a semiconductor chip having the through-hole electrode 49 is completed.

FIGS. 12A and 123 each show one example of a part of the semiconductor device prepared in accordance with the manufacturing method described in the foregoing. FIGS. 12A and 125 show two through-hole electrodes 49 and the wiring layer 48 connecting between the through-hole electrodes 49. FIGS. 12A and 12B each show a state before the protection film 63 is formed. FIG. 12A shows a cross-sectional structure of the through-hole electrode 49. FIG. 12B schematically shows the structure of the two through-hole electrodes 49 and the wiring layer 48 connecting between the through-hole electrodes 49 as seen from above. FIG. 12B shows the two through-hole electrodes 49, the wiring layer 48 connecting between the through-hole electrodes 49, and the second insulating film 58 intended to insulate them from the surrounding.

### CITATION LIST

### Patent Literatures

PATENT LITERATURE 1: Japanese Unexamined Patent Publication No. 2006-128171
PATENT LITERATURE 2: Japanese Unexamined Patent Publication No. 2003-198122

### SUMMARY OF THE INVENTION

### Technical Problem

However, with the semiconductor device and the manufacturing method thereof of Conventional Example 1 disclosed in PATENT LITERATURE 1, the wiring formation layer, the seed metal layer, and the barrier metal layer are subjected to pattern formation by wet etching. The thickness of the wiring formation layer, that of the seed metal layer, and that of the barrier metal layer are as thick as 7 μm to 10 μm in total. This necessitates a wet etching time of 70 to 100 minutes. Therefore, with the method of Conventional Example 1, there is an issue of an increase both in the processing time and in the processing cost.

Further, with the semiconductor device and the manufacturing method thereof of Conventional Example 2 disclosed in PATENT LITERATURE 2, in forming the wiring formation layer, using the second resist as a mask, the wiring formation layer solely is selectively formed by plating. Accordingly, only the seed metal layer and the barrier metal layer in a region except for the wiring formation layer region should be removed. However, the thickness of the seed metal layer and that of the barrier metal layer are as thick as 2 pinto 3 μm in total, which necessitates wet etching time of 20 to 30 minutes. Though the processing time and the processing cost are smaller than those of Conventional Example 1, the method of Conventional Example 2 still has an issue of the required processing time and processing cost. Further, since the wiring formation layer formed by plating is used as a mask, a reduction in the thickness of the wiring formation layer when the seed metal layer and the barrier metal layer are subjected to wet etching is great, and consequently, it also involves an issue of inviting variations in the electric characteristic of the semiconductor device.

In consideration of the conventional issues described above, an object of the present invention is to provide, in connection with a semiconductor device having a through-hole electrode and a manufacturing method thereof, a semiconductor device and a manufacturing method thereof that can reduce the processing time in the wet etching step.

### Solution to Problem

The present invention is structured as follows in order to achieve the object stated above.

A semiconductor device of the present invention is characterized by comprising:

an electronic device formed on a front surface of a semiconductor substrate;

a pad electrode being established an electric conduction with the electronic device;

a through-hole electrode that penetrates through the semiconductor substrate in a thickness direction thereof;

a wiring layer formed on a back surface of the semiconductor substrate to connect between the through-hole electrodes;

a conductive terminal connected to the wiring layer or the through-hole electrode; and

a groove for forming insulating portion formed to surround the through-hole electrode and the wiring layer on the back surface of the semiconductor substrate.

A semiconductor device manufacturing method of the present invention is characterized by comprising: forming a through-hole electrode that penetrates through a semiconductor substrate having an electronic device and a pad electrode disposed on its front surface from a back surface of the semiconductor substrate in a thickness direction thereof to establish an electric conduction with the pad electrode on the front surface of the semiconductor substrate; and forming a wiring layer that establishes an electric conduction with the through-hole electrode and that is disposed on the back surface of the semiconductor substrate, the method comprising:

forming a via hole for the through-hole electrode extending from the back surface of the semiconductor substrate in the thickness direction of the semiconductor substrate; and

forming a groove for forming insulating portion so as to surround the through-hole electrode and the wiring layer, before forming an insulating portion in the via hole.

### Effects of the Invention

As described above, the present invention can reduce the processing time of the wet etching step. Further, the shortened processing time of the wet etching step realizes a reduction in the thinning of the wiring formation layer when the conductive layers (e.g., the seed metal layer and the barrier metal layer) are subjected to wet etching, and a reduction in the variation in the electric characteristic. Accordingly, a semiconductor device being high in the reliability of the electric characteristic can be provided.

### BRIEF DESCRIPTION OF THE DRAWINGS

These and other objects and features of the present invention will become apparent from the following description in connection with preferred embodiments taken in conjunction with the accompanying drawings, in which:

FIG. 1 is a flowchart of a semiconductor device manufacturing method according to a first embodiment of the present invention;

FIG. 2A is a cross-sectional view at a time point when a support member is formed by bonding to the semiconductor substrate according to the semiconductor device manufacturing method of the first embodiment;

FIG. 2B is a cross-sectional view at a time point when a resist for a through via hole is formed according to the semiconductor device manufacturing method of the first embodiment;

FIG. 2C is a cross-sectional view at a time point when the through via hole is formed according to the semiconductor device manufacturing method of the first embodiment;

FIG. 2D is a cross-sectional view at a time point when a resist for a dummy groove hole for forming insulating portion is formed according to the semiconductor device manufacturing method of the first embodiment;

FIG. 2E is a cross-sectional view at a time point when the dummy groove hole for forming insulating portion is formed according to the semiconductor device manufacturing method of the first embodiment;

FIG. 2F is a cross-sectional view at a time point when an insulating film layer is formed according to the semiconductor device manufacturing method of the first embodiment;

FIG. 2G is a cross-sectional view at a time point when the insulating film is removed by etch back according to the semiconductor device manufacturing method of the first embodiment;

FIG. 2H is a cross-sectional view at a time point when a barrier metal layer is formed according to the semiconductor device manufacturing method of the first embodiment;

FIG. 2I is a cross-sectional view at a time point when a seed metal layer is formed according to the semiconductor device manufacturing method of the first embodiment;

FIG. 2J is a cross-sectional view at a time point when a resist for a wiring is formed according to the semiconductor device manufacturing method of the first embodiment;

FIG. 2K is a cross-sectional view at a time point when the wiring layer is formed according to the semiconductor device manufacturing method of the first embodiment;

FIG. 2L, is a cross-sectional view at a time point when the resist is removed according to the semiconductor device manufacturing method of the first embodiment;

FIG. 2M is a cross-sectional view at a time point when the seed metal layer and the barrier metal layer are removed according to the semiconductor device manufacturing method of the first embodiment;

FIG. 2N is a cross-sectional view at a time point when a protection layer is formed according to the semiconductor device manufacturing method of the first embodiment;

FIG. 3A is a cross-sectional view at a time point before a protection film is formed in one example of the structure of the semiconductor device according to the first embodiment;

FIG. 3B is a view of two through-hole electrodes and a wiring between the through-hole electrodes in one example in the structure of the semiconductor device according to the first embodiment as seen from above;

FIG. 3C is a view of two through-hole electrodes and a wiring between the through-hole electrodes, and wirings each between an external terminal and the through-hole electrode in another example in the structure of the semiconductor device of the first embodiment as seen from above;

FIG. 4 is a flowchart of a semiconductor device manufacturing method according to a second embodiment of the present invention;

FIG. 5A is a cross-sectional view at a time point when a support member is formed by bonding to the semiconductor substrate according to the semiconductor device manufacturing method of the second embodiment;

FIG. 5B is a cross-sectional view at a time point when a resist for a through via hole and for a dummy groove hole for forming insulating portion is formed in the semiconductor device manufacturing method shown in FIG. 5A;

FIG. 5C is a cross-sectional view at a time point when the through via hole and the dummy groove hole for forming insulating portion are formed according to the semiconductor device manufacturing method of the second embodiment;

FIG. 5D is a cross-sectional view at a time point where an insulating film layer is formed according to the semiconductor device manufacturing method of the second embodiment;

FIG. 5E is a cross-sectional view at a time point when the insulating film is removed by etch back according to the semiconductor device manufacturing method of the second embodiment;

FIG. 5F is a cross-sectional view at a time point when a barrier metal layer is formed according to the semiconductor device manufacturing method of the second embodiment;

FIG. 5G is a cross-sectional view at a time point when a seed metal layer is formed in the semiconductor device manufacturing method of the second embodiment;

FIG. 5H is a cross-sectional view at a time point when a resist for a wiring is formed according to the semiconductor device manufacturing method of the second embodiment;

FIG. 5I is a cross-sectional view at a time point when the wiring layer is formed according to the semiconductor device manufacturing method of the second embodiment;

FIG. 5J is a cross-sectional view at a time point when the resist is removed according to the semiconductor device manufacturing method of the second embodiment;

FIG. 5K is a cross-sectional view at a time point when the seed metal layer and the barrier metal layer are removed according to the semiconductor device manufacturing method of the second embodiment;

FIG. 5L is a cross-sectional view at a time point when a protection layer is formed according to the semiconductor device manufacturing method of the second embodiment;

FIG. 6A is a cross-sectional view of one example of the structure of the semiconductor device according to the second embodiment before a protection film is formed;

FIG. 6B is a view of two through-hole electrodes and a wiring between the through-hole electrodes in one example in the structure of the semiconductor device in one example shown in FIG. 6A as seen from above;

FIG. 6C is a cross-sectional view for describing the relationship between a through hole diameter (φ₁ of an opening (an opening on the back surface of the semiconductor substrate) of a via hole for forming a through-hole electrode and a groove width L₂ of an opening (an opening on the back surface of the semiconductor substrate) of a dummy groove hole portion for forming insulating portion that insulates the wirings from each other, in the structure of the semiconductor device according to the second embodiment;

FIG. 7 is a flowchart of a semiconductor device manufacturing method according to Conventional Example 1;

FIG. 8A is a cross-sectional view at a time point when a support member is formed by bonding to the semiconductor substrate according to the semiconductor device manufacturing method of Conventional Example 1;

FIG. 8B is a cross-sectional view at a time point when a resist for a through via hole is formed according to the semiconductor device manufacturing method of Conventional Example 1;

FIG. 8C is a cross-sectional view at a time point when the through via hole is formed according to the semiconductor device manufacturing method of Conventional Example 1;

FIG. 8D is a cross-sectional view at a time point when an insulating film layer is formed according to the semiconductor device manufacturing method of Conventional Example 1;

FIG. 8E is a cross-sectional view at a time point when the insulating film is removed by etch back according to the semiconductor device manufacturing method of Conventional Example 1;

FIG. 8F is a cross-sectional view at a time point when a barrier metal layer and a seed metal layer are formed according to the semiconductor device manufacturing method of Conventional Example 1;

FIG. 8G is a cross-sectional view at a time point when a wiring layer is formed according to the semiconductor device manufacturing method of Conventional Example 1;

FIG. 8H is a cross-sectional view, at a time point when a resist for a wiring is formed according to the semiconductor device manufacturing method of Conventional Example 1;

FIG. 8I is a cross-sectional view at a time point when the seed metal layer and the barrier metal layer are removed according to the semiconductor device manufacturing method of Conventional Example 1;

FIG. 8J is a cross-sectional view at a time point when the resist is removed according to the semiconductor device manufacturing method of Conventional Example 1;

FIG. 8K is a cross-sectional view at a time point when a protection layer is formed according to the semiconductor device manufacturing method of Conventional Example 1;

FIG. 9A is a cross-sectional view of one example of the structure of the semiconductor device according to Conventional Example 1 before a protection film is formed;

FIG. 9B is a view of two through-hole electrodes and a wiring between the through-hole electrodes in one example in the structure of the semiconductor device according to Conventional Example 1 as seen from above;

FIG. 10 is a flowchart of a semiconductor device manufacturing method according to Conventional Example 2;

FIG. 11A is a cross-sectional view at a time point when a support member is formed by bonding to the semiconductor substrate according to the semiconductor device manufacturing method of Conventional Example 2;

FIG. 11B is a cross-sectional view at a time point when a resist for a through via hole is formed according to the semiconductor device manufacturing method of Conventional Example 2;

FIG. 11C is a cross-sectional view at a time point when a through via hole is formed according to the semiconductor device manufacturing method of Conventional Example 2;

FIG. 11D is a cross-sectional view at a time point when an insulating film layer is formed according to the semiconductor device manufacturing method of Conventional Example 2;

FIG. 11E is a cross-sectional view at a time point when the insulating film is removed by etch back according to the semiconductor device manufacturing method of Conventional Example 2;

FIG. 11F is a cross-sectional view at a time point when a barrier metal layer and a seed metal layer are formed according to the semiconductor device manufacturing method of Conventional Example 2;

FIG. 11G is a cross-sectional view at a time point when a resist for a wiring is formed according to the semiconductor device manufacturing method of Conventional Example 2;

FIG. 11H is a cross-sectional view at a time point when the wiring layer is formed in the semiconductor device manufacturing method of Conventional Example 2;

FIG. 11I is a cross-sectional view at a time point when the resist is removed according to the semiconductor device manufacturing method of Conventional Example 2;

FIG. 11J is a cross-sectional view at a time point when the seed metal layer and the barrier metal layer are removed in accordance with the semiconductor device manufacturing method of Conventional Example 2;

FIG. 11K is a cross-sectional view at a time point when a protection layer is formed according to the semiconductor device manufacturing method of Conventional Example 2;

FIG. 12A is a cross-sectional view of one example of the structure of the semiconductor device according to Conventional Example 2 before a protection film is formed; and

FIG. 12B is a view of two through-hole electrodes and a wiring between the through-hole electrodes in one example in the structure of the semiconductor device according to Conventional Example 2 as seen from above.

### DESCRIPTION OF EMBODIMENTS

In the following, with reference to the drawings, a description will be given of embodiments of the present invention. It is to be noted that, in the following description, identical structures are denoted by identical reference characters, and the description thereof is omitted as appropriate.

### First Embodiment

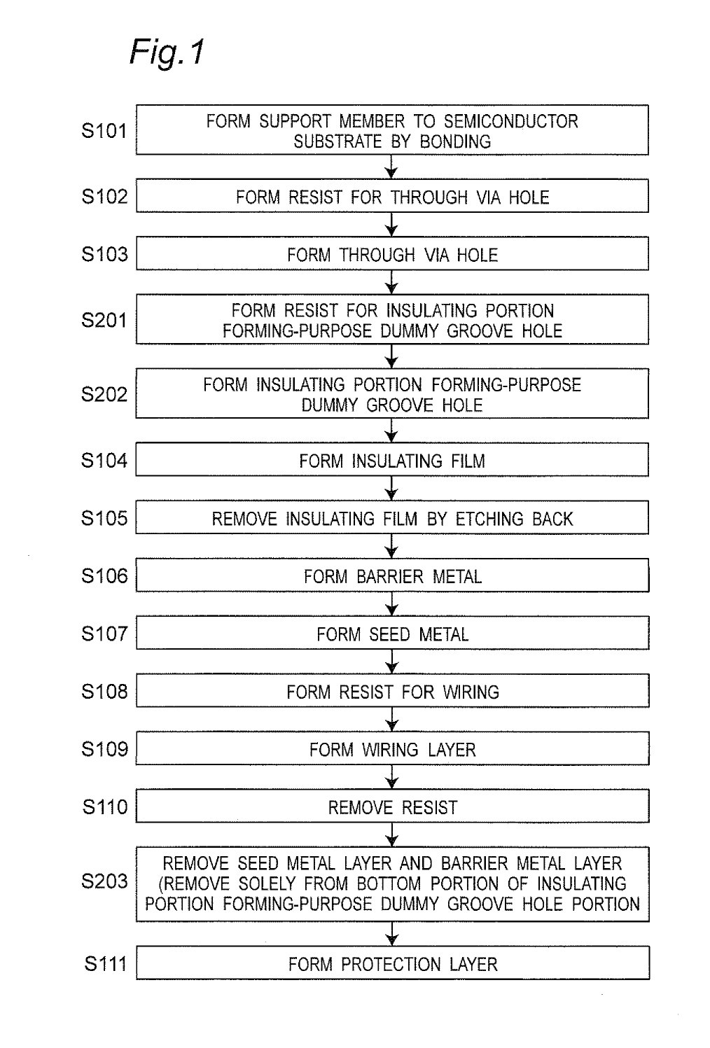

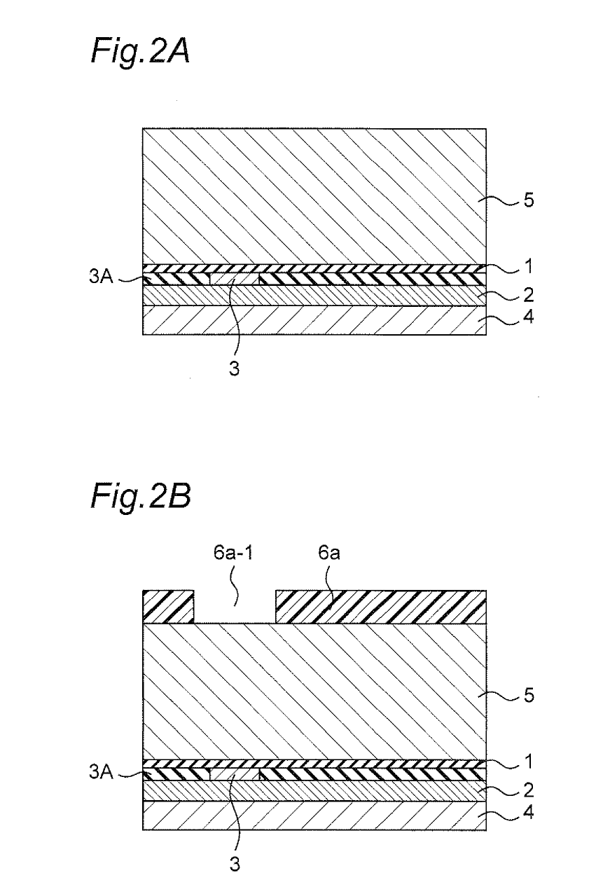

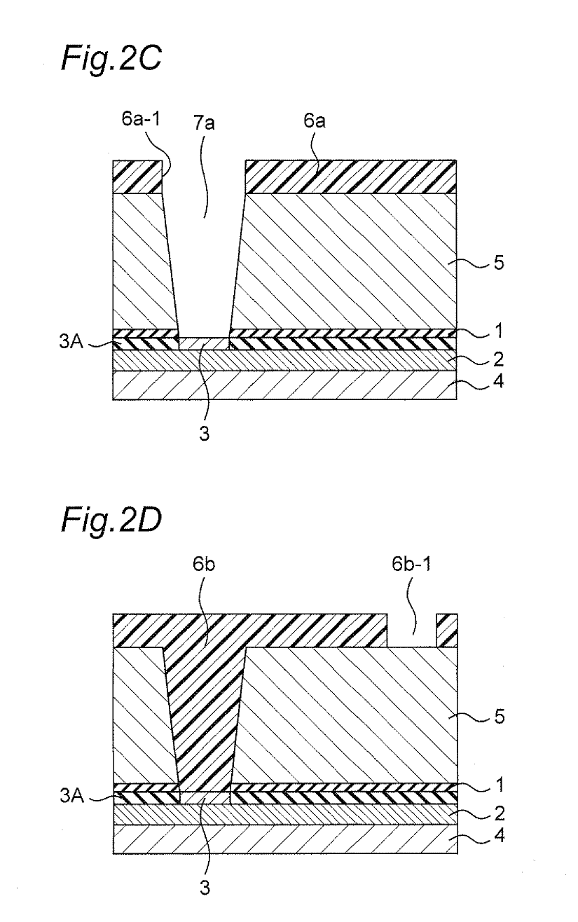

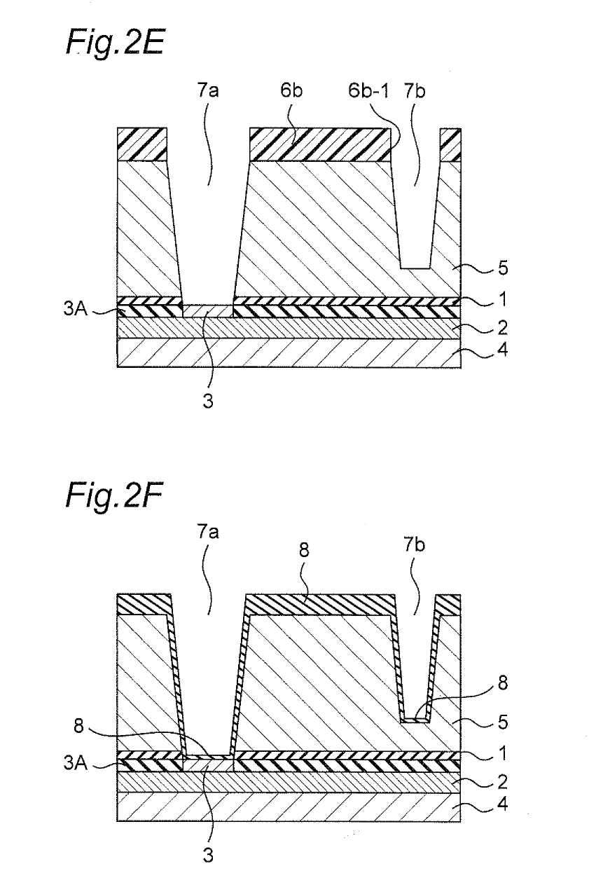

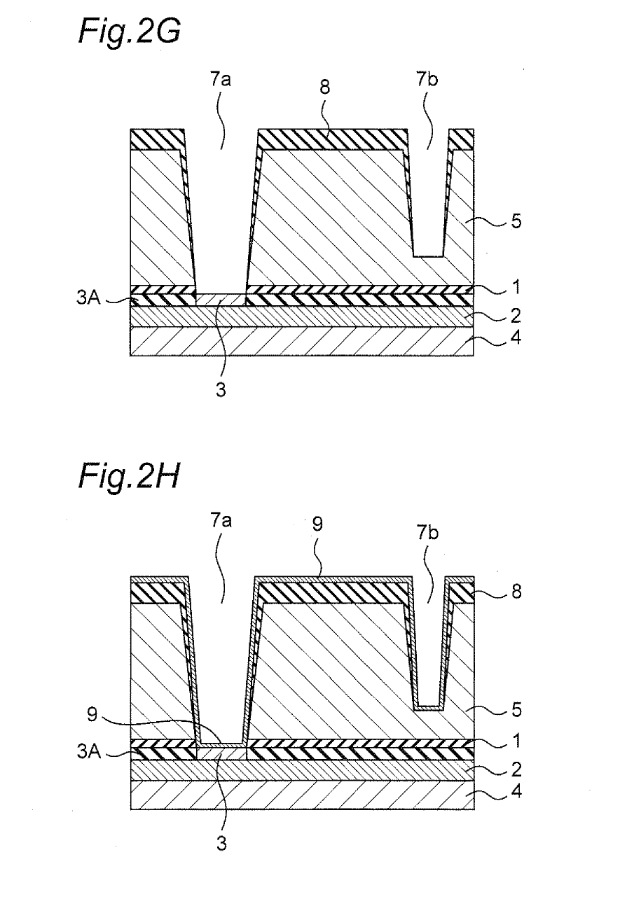

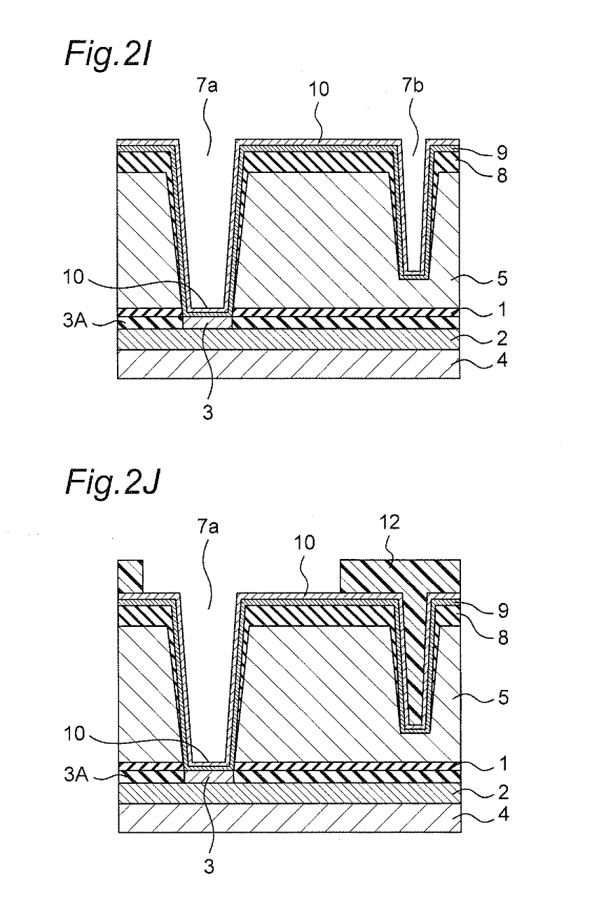

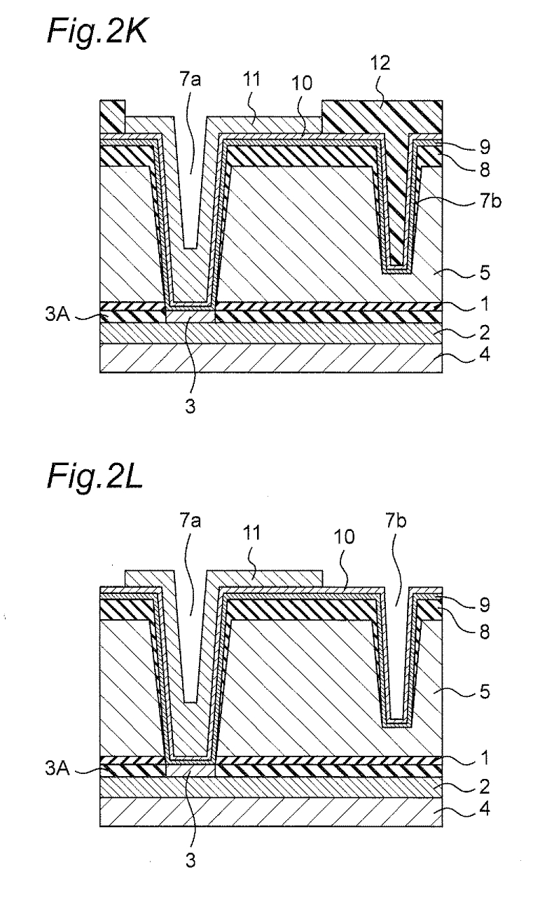

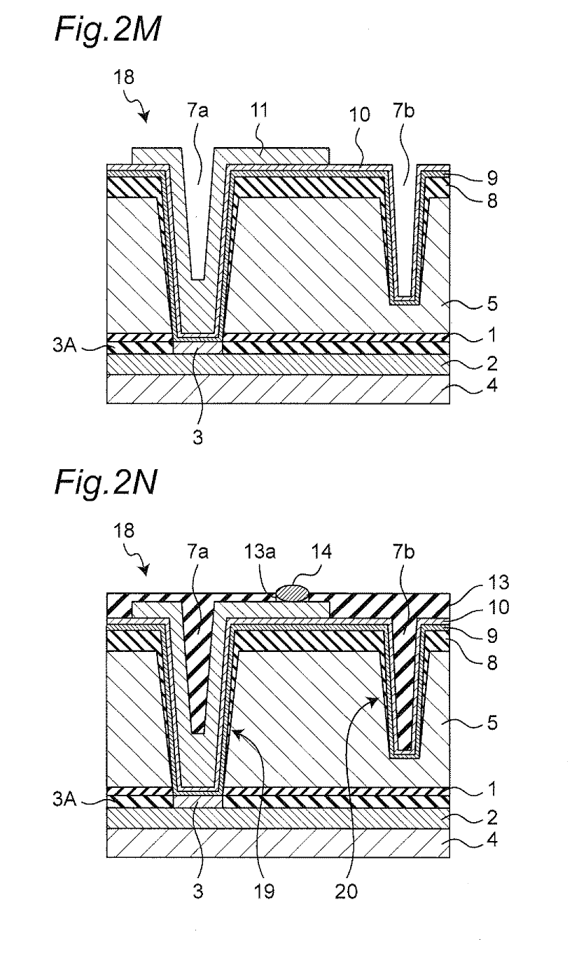

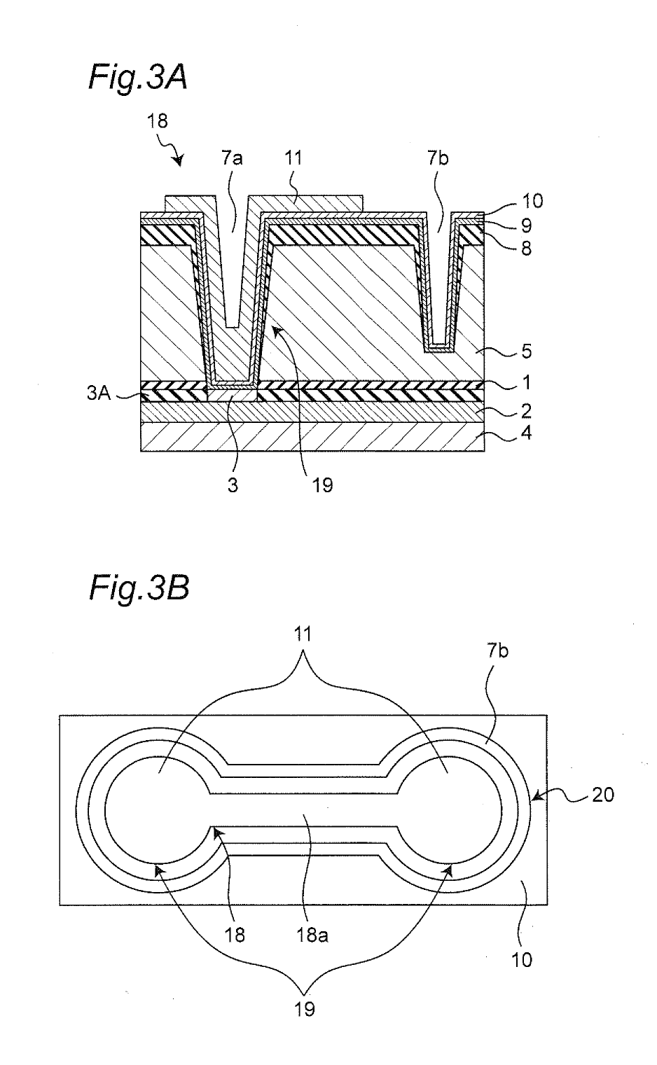

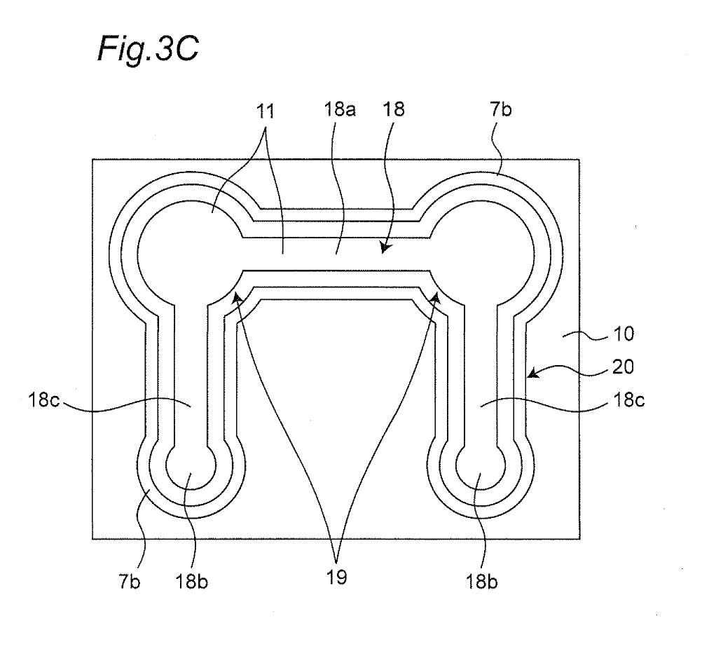

In the following, in connection with a semiconductor device according to a first embodiment of the present invention, a description will be given of an overview of a manufacturing method thereof. FIG. 1 is the flowchart of the semiconductor device manufacturing method according to the first embodiment, and FIGS. 2A to 2N are cross-sectional views at respective stages (steps). A description will be given of the semiconductor device prepared in accordance with the manufacturing method with reference to FIGS. 3A, 3B, and 3C.

First, as shown in FIG. 2A, a support member 4 is bonded on the front surfaces (the bottom surface in FIG. 2A) of an electronic device 2 and a semiconductor substrate 5, having a first insulating film 1 and a resin layer possessing an adhesion function (not shown) interposed therebetween (step S101). Here, the electronic device 2 is a light receiving element such as a CCD, an infrared sensor or the like, or a light emitting element, or the like, for example. Further, on the semiconductor substrate 5, a pad electrode 3 being an external connection-purpose electrode connected to the electronic device 2 is formed. The semiconductor substrate 5 is structured with a silicon substrate, for example. The resin layer possessing an adhesion function refers to an adhesion layer. It is to be noted that the support member 4 should be bonded as necessary, and is not necessarily bonded. Further, the insulating protection layer 3A is a layer disposed to surround the pad electrode 3.

Subsequently, on the back surface (the top surface in FIG. 2B) of the semiconductor substrate 5, a through-hole electrode forming-purpose via hole 7a that penetrates through the semiconductor substrate 5 to reach the first insulating film 1 immediately above the pad electrode 3 is formed. For this purpose, first, on the back surface (the top surface in FIG. 2B) of the first semiconductor substrate 5, a resist layer (a resist via pattern layer) 6a is formed (step S102). The resist layer 6a is provided with an opening 6a-1 at a portion where the via hole 7a is to be formed.

Next, as shown in FIG. 2C, using the resist layer 6a as a mask, the hole electrode hole 7a extending from the back surface of the semiconductor substrate 5 to reach the first insulating film 1 immediately above the pad electrode 3 is formed by dry etching (step S103). As the etching gas, for example, a gas that contains SF₆, O₂, C₄F₈, or the like is used. At the bottom portion of the via hole 7a, the first insulating film 1 is exposed. Subsequently, using the resist layer 6a used in performing dry etching to the via hole 7a as a mask, the first insulating film 1 at the bottom portion of the via hole 7a is removed by dry etching using the opening 6a-1. As the etching gas, for example, a gas that contains CF₄, O₂, O₄₃₈, or the like is used. Thus, at the bottom portion of the via hole 7a, the pad electrode 3 is partially exposed. Thereafter, the resist layer 6a is removed from the back surface of the semiconductor substrate 5.

Subsequently, at the back surface of the semiconductor substrate 5, a frame-like dummy groove hole portion for forming insulating portion (one example of a groove for forming insulating portion) 7b is formed. In order to form the dummy groove hole portion 7b, first, as shown in FIG. 2D, a resist pattern layer 6b is formed (step S201). At a portion of the resist pattern layer 6b where the dummy groove hole portion 7b is to be formed, the frame-like opening groove portion 6b-1 is formed. The resist pattern layer 6b is formed to entirely bury the via hole 7a.

Next, using the resist pattern layer 6b as a mask, the dummy groove hole portion 7b is formed by dry etching (step S202). The dummy groove hole portion 7b is formed to extend in the thickness direction from the front surface of the semiconductor substrate 5 toward the back surface thereof so as not to penetrate therethrough. The bottom portion of the dummy groove hole portion 7b is positioned at an intermediate portion in the thickness direction of the semiconductor substrate 5. As the etching gas, for example, a gas containing SF₆, O₂, C₄F₈, or the like is used. Thereafter, as shown in FIG. 2E, the resist pattern layer 6b is removed from the back surface of the semiconductor substrate 5.

Next, as shown in FIG. 2F, on the back surface of the semiconductor substrate 5 including the inside of the via hole 7a and the inside of the dummy groove hole portion 7b, a second insulating film 8 is formed (step S104). Here, the thickness of the second insulating film 8 at the bottom portion of the via hole 7a becomes thinner than the thickness of the second insulating film 8 formed on the back surface of the semiconductor substrate 5, in accordance with the depth of the via hole 7a. Similarly, the thickness of the second insulating film 8 at the bottom portion of the dummy groove hole portion 7b becomes thinner than the thickness of the second insulating film 8 formed on the back surface of the semiconductor substrate 5, in accordance with the depth of the dummy groove hole portion 7b.

Next, as shown in FIG. 2G, to the semiconductor substrate 5 provided with the second insulating film 8, the second insulating film 8 is etched preferably by anisotropic dry etching (step S105). By this etching, at the bottom portion of the via hole 7a and the bottom portion of the dummy groove hole portion 7b, the second insulating film 8 is removed to partially expose the pad electrode 3. However, at the back surface of the semiconductor substrate 5, the side inner wall of the via hole 7a, and the side inner wall of the dummy groove hole portion 7b, the second insulating film 8 remains.

Next, as shown in FIG. 2H, a conductive barrier metal layer 9 is formed on the entire surface of the second, insulating film 8 including: the side inner wall of the via hole 7a; the side inner wall and the bottom surface of the dummy groove hole portion 7b; the back surface of the semiconductor substrate 5; and on the part of the pad electrode 3 exposed at the bottom portion of the via hole 7a (step S106). Here, the barrier metal layer 9 is formed with a metal layer of, e.g., a titanium tungsten layer, a titanium nitride layer, a tantalum nitride layer, or the like. Further, the barrier metal layer 9 is formed by a film growth method such as sputtering, CVD, or the like, for example.

Next, as shown in FIG. 2I, a conductive seed metal layer 10 is formed on the entire surface of the barrier metal layer 9 including: the side inner wall of the via hole 7a; the side inner wall and the bottom surface of the dummy groove hole portion 7b; the back surface of the semiconductor substrate 5, and on the entire surface of the barrier metal layer 9 on the part of the pad electrode 3 exposed at the bottom portion of the via hole 7a (step S107). The seed metal layer 10 is a layer to be an electrode to form a wiring formation layer, whose description will be given later, by plating, and is structured with metal such as copper or the like.

Next, as shown in FIG. 2J, a second resist layer 12 is formed at a prescribed region on the seed metal layer 10 (step S108). Here, the prescribed region where the second resist layer 12 is to be formed is a region except for the formation region of the via hole 7a. Further, the prescribed region where the second resist layer 12 is to be formed is a region on the back surface of the semiconductor substrate 5 where a wiring layer 18 having a prescribed pattern, whose description will be given later, is not to be formed. The second resist layer 12 is formed to entirely bury the inside of the dummy groove hole portion 7b.

Next, as shown in FIG. 2K, using the second resist layer 12 as a mask, a wiring formation layer 11 is formed at the side inner wall and the bottom surface of the via hole 7a, and a region on the back surface of the semiconductor substrate 5 where the wiring layer 18 is to be formed (step S109). The wiring formation layer 11 is a metal layer structured with, e.g., copper, by the electrolytic plating process, for example.

Next, as shown in FIG. 2L, the second resist 12 is removed (step S110). For removing the second resist layer 12, the asking process is used, for example.

Next, as shown in FIG. 2M, using the wiring formation layer 11 as a mask, the seed metal layer 10 and the barrier metal layer 9 at the bottom portion of the dummy groove hole portion 7b b is removed (step S203). Patterning carried out by removal of the seed metal layer 10 and the barrier metal layer 9 is carried out by wet etching, for example. Here, the thickness of the seed metal layer 10 not covered by the wiring formation layer 11, the seed metal layer 10 at other portions such as at the back surface of the semiconductor substrate 5 and at the inner sidewall of the dummy groove hole portion 7b, somewhat becomes thinner. Here, the seed metal layer 10 and the barrier metal layer 9 removed by wet etching should be just those at the bottom portion of the dummy groove hole portion 7b. The seed metal layer 10 and the barrier metal layer 9 on the back surface of the semiconductor substrate 5 may remain after patterning by wet etching is carried out.

Next, as shown in FIG. 2N, a protection layer 13 as one example of the insulating layer is formed on the entire back surface of the semiconductor substrate 5 including the inside of the via hole 7a and the inside of the dummy groove hole portion 7b, so as to cover them (step S111). Here, the entire back surface of the semiconductor substrate 5 refers to the top of the seed metal layer 10 and the wiring formation layer 11 and the like, i.e., the top of the through-hole electrode 19 (a conductor portion structured with a part of the wiring formation layer 11, the seed metal layer 10, and the barrier metal layer 9) and the wiring layer 18. The protection layer 13 is structured with an insulating resist material or the like, for example. The protection layer 13 is provided with an opening 13a at the position corresponding to the wiring layer 18. Then, on the wiring layer 18 exposed at the opening 13a, a ball-like conductive terminal 14 made of metal, e.g., solder or the like, is formed. It is to be noted that, at the bottom portion of the dummy groove hole portion 7b, the insulating material of the protection layer 13 disposed in the dummy groove hole portion 7b and the material structuring the semiconductor substrate are in direct contact with each other, so as to exhibit insulation. Hence, by the protection layer 13 being inserted into the dummy groove hole portion 7b such that the dummy groove hole portion 7b is filled therewith, a frame-like insulating portion 20 is formed.

Next, along a not-shown dicing line, the semiconductor substrate 5 is subjected to dicing. Thus, a plurality of semiconductor devices each being a semiconductor chip having the through-hole electrode 19 is completed.

FIGS. 3A and 3B each show one example of a part of the semiconductor device prepared in accordance with the manufacturing method described in the foregoing. FIGS. 3A and 3B show two through-hole electrodes 19 and the wiring layer 18 connecting between the through-hole electrodes 19. It is to be noted that FIGS. 3A and 33 each show a state before the protection film 13 is formed. FIG. 3A shows a cross-sectional structure of the through-hole electrode 19. FIG. 35 schematically shows the structure of the two through-hole electrodes 19 and the wiring layer (rewiring layer) 18 connecting between the through-hole electrodes 19 as seen from above. In FIG. 3B, the top portion of the semiconductor device is structured with the two through-hole electrodes 19, a wiring portion 18a connecting between the through-hole electrodes 19, and a frame-like insulating portion 20 intended to insulate the two through-hole electrodes 19 and the wiring portion 18a from the surrounding. The frame-like insulating portion 20 is disposed in a frame-like manner, so as to surround the two through-hole electrodes 19 and the wiring portion 18a while being away from them by a prescribed interval. Here, what is referred to by the disposition so as to surround the two through-hole electrodes 19 and the wiring portion 18a while being away from them by a prescribed interval is, in other words, a disposition conforming to the outer shape of the two through-hole electrodes 19 and the wiring portion 18a. By such a disposition conforming to the outer shape, even in a case where each through-hole electrode 19 is arranged at a narrow pitch, a high-density wiring can be achieved. Thus, it is more suitable for a semiconductor substrate having high-density wirings. However, the frame-like insulating portion 20 is only required to surround the two through-hole electrodes 19 and the wiring portion 18a, such that they are insulated from other through-hole electrode 19 or wiring portion 18a. Therefore, it goes without saying that the insulating portion 20 is not limited to a frame-like shape conforming to the outer shape of the two through-hole electrodes 19 and the wiring portion 18a, and it may be a simple quadrilateral shape, an oval shape or the like.

The wiring layer 18 structures the wiring portion 18a that functions as a rewiring layer electrically connecting a plurality of through-hole electrodes 19 to one another, for example. It is to be noted that, as shown in FIG. 3C, the wiring layer 18 may be structured to further include external terminals 18b, second wiring portions 18c connecting between the external terminals 18b and the through-hole electrode 19 or the wiring portion 18a. That is, FIG. 3C schematically shows the structure of the wiring layer 18 including the two through-hole electrodes 19, the wiring portion 18a connecting between the through-hole electrodes 19, the external terminals 18b, the second wiring portions 18c connecting between the external terminals 18b and the through-hole electrodes 19 as seen from above. In FIG. 30, the top portion of the semiconductor device is structured with the two through-hole electrodes 19, two wiring layers 18a and second wiring portions 18c, the external terminals 18b, and the frame-like insulating portion 20 intended to insulate them from the surrounding.

In accordance with such a semiconductor device manufacturing method, for insulating the through-hole electrode 19 and the wiring layer 18 from other wirings, removal of the seed metal layer 10 and the barrier metal layer 9 at the bottom portion of the frame-like insulating portion forming-purpose dummy groove hole portion (insulating portion forming-purpose dummy groove hole portion) 7b will suffice. Accordingly, use of the semiconductor manufacturing method according to the present embodiment eliminates the necessity of removing the conductive layers (the seed metal layer 10 and the barrier metal layer 9) at other portions such as the side inner wall of the dummy groove hole portion 7b. Accordingly, the present embodiment is capable of drastically shortening the wet etching time to be as 1/10 to ⅕ (i.e., 2 to 6 minutes) as compared with the wet etching time (20 to 30 minutes) disclosed in Conventional Example 2. Accordingly, it becomes possible to provide a semiconductor device and a manufacturing method thereof that can drastically reduce the processing time and processing cost for the wet etching step of the wiring formation layer 11, the seed metal layer 10, and the barrier metal layer 9. It is to be noted that, of Conventional Examples 1 and 2, Conventional Example 2 is a conventional example that is advantageous in terms of the processing time of the wet etching step of the wiring formation layer 11, the seed metal layer 10, and the barrier metal layer 9.

Further, as described in the foregoing, since the wet etching time is shortened, a great reduction in the thinning of the wiring formation layer 11 when the seed metal layer 10 and the barrier metal layer 9 are subjected to wet etching can be achieved, and a drastic reduction in the variation of the electric characteristic can be achieved. Accordingly, semiconductor device and a manufacturing method thereof being high in the reliability of the electric characteristic can be provided.

Further, the semiconductor device of the present embodiment has the frame-like insulating portion 20 that surrounds the through-hole electrode 19 and the wiring layer 18 on the back surface of the semiconductor substrate 5, the frame-like insulating portion 20 insulating from other through-hole electrode 19 and rewiring layer 18. Therefore, structuring the insulating material of the frame-like insulating portion 20, that is, the material of the protection layer 13, with a resin material such as resist that is softer than the semiconductor substrate 5, e.g., silicon of the silicon substrate, it becomes possible to provide the function of stress relaxation. In this case, the stress acting on the semiconductor device can be relieved by the insulating material inside the frame-like insulating portion 20.

### Second Embodiment

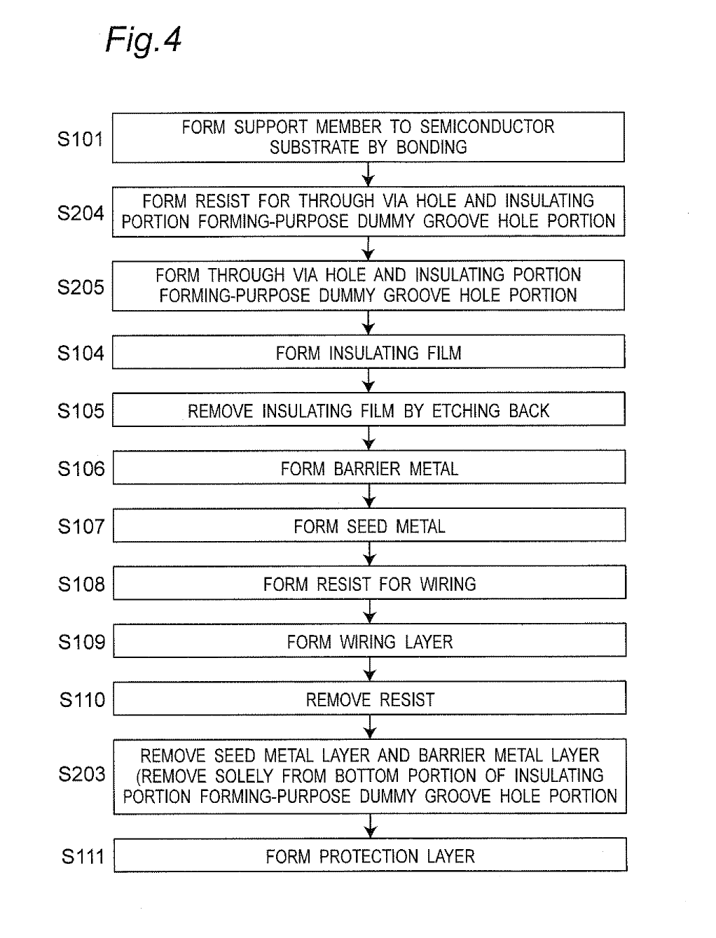

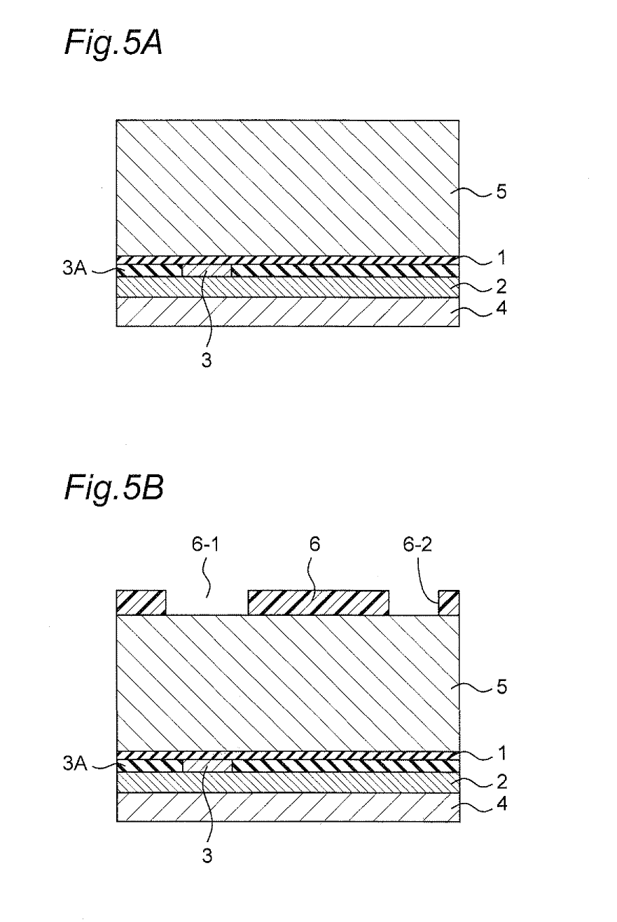

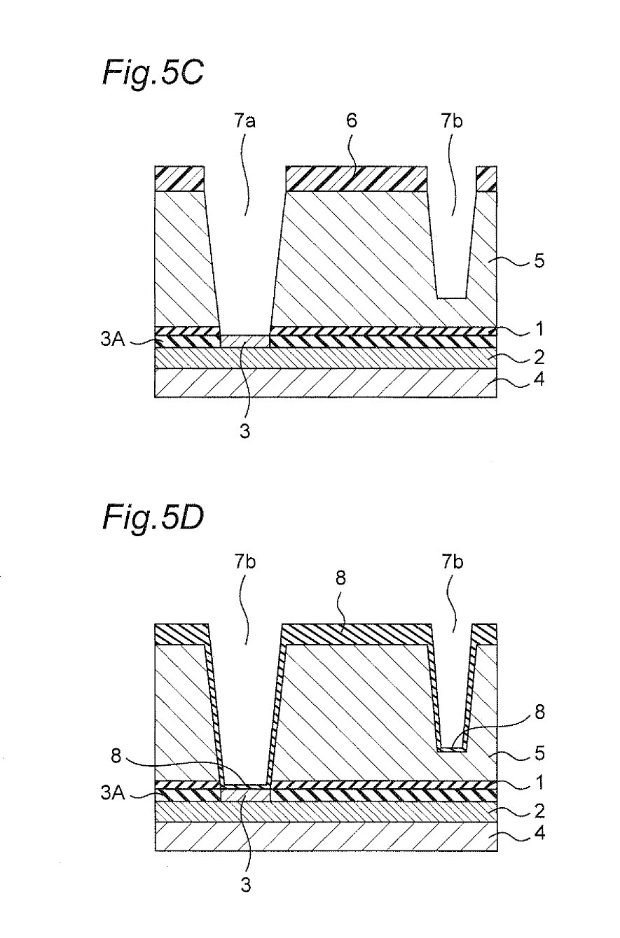

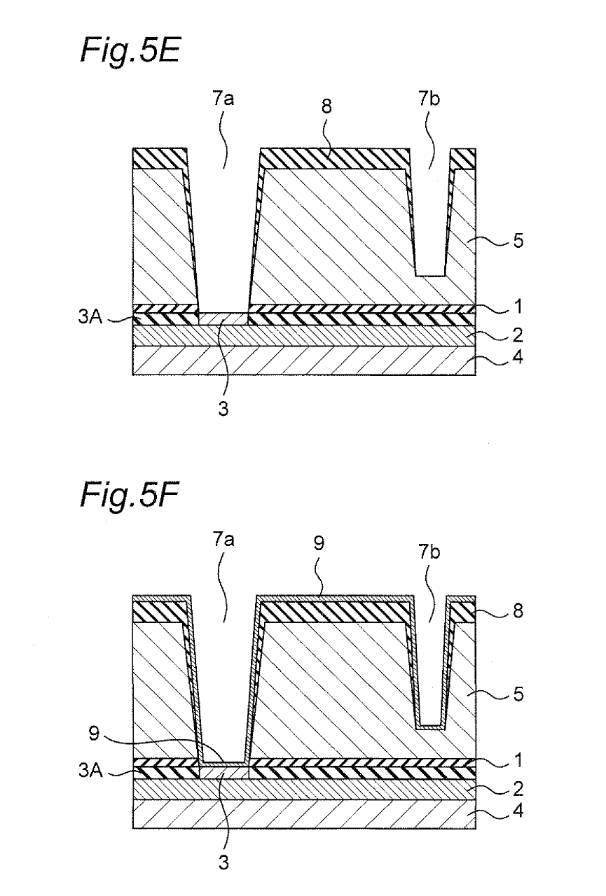

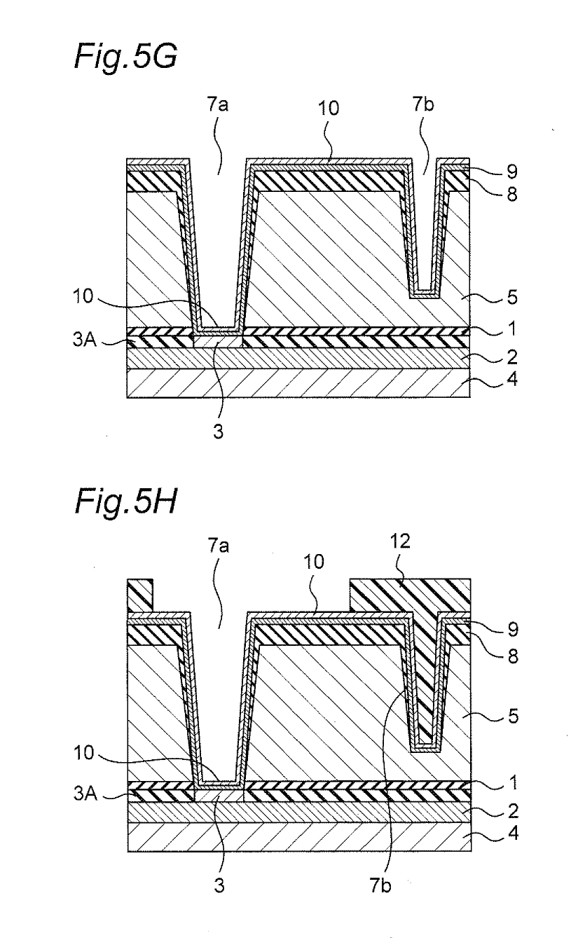

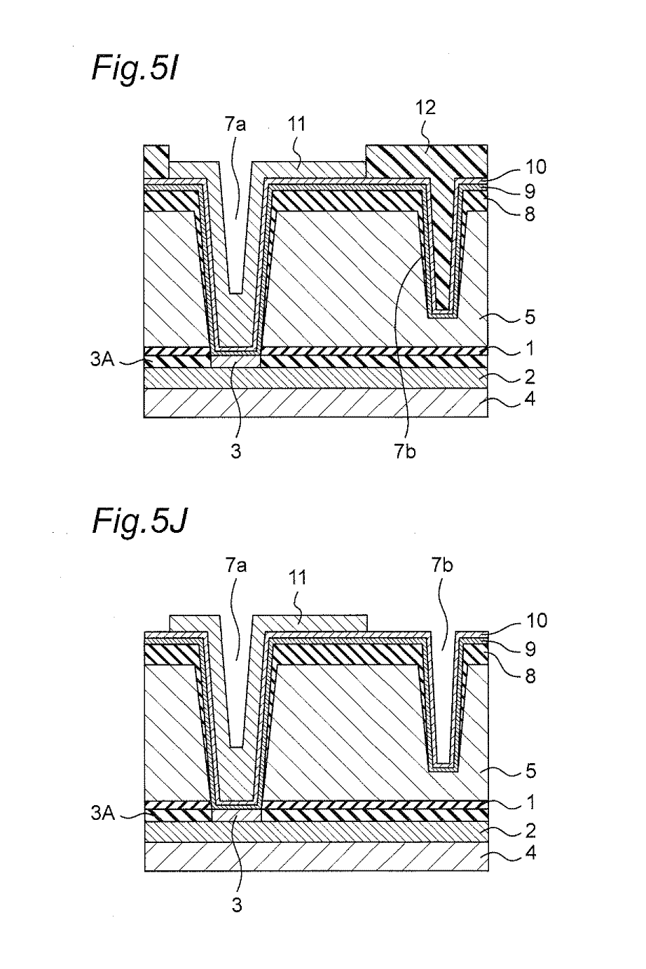

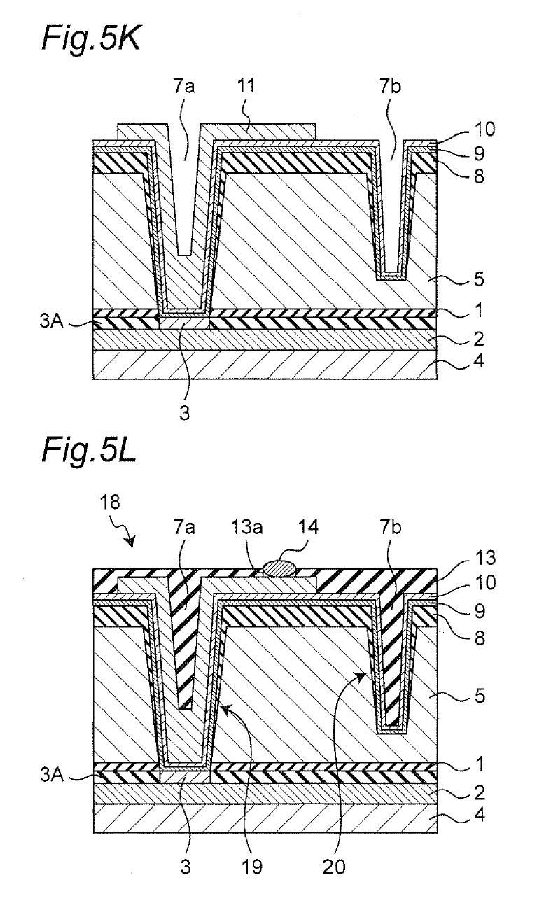

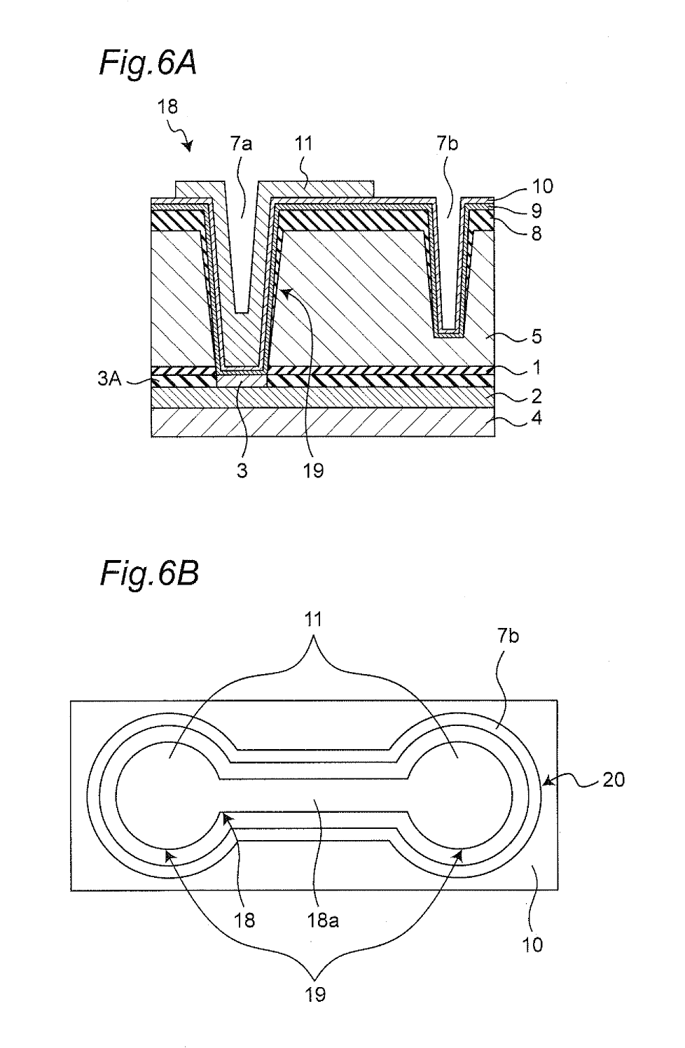

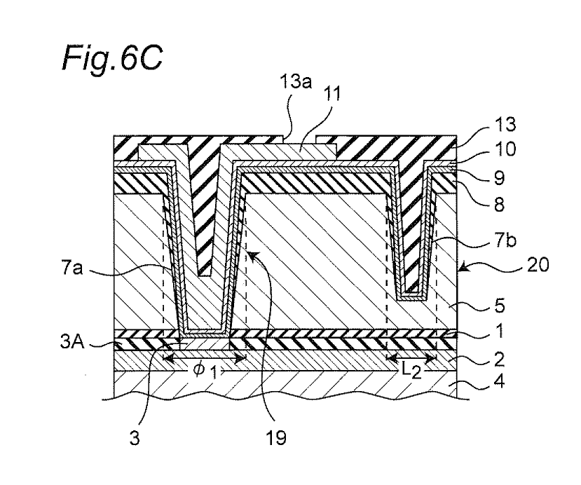

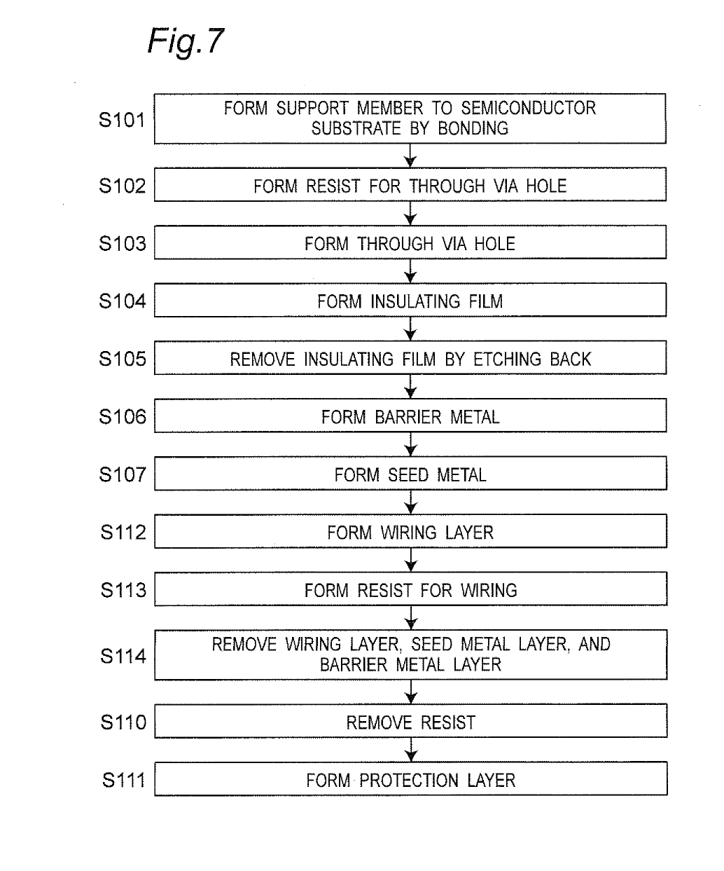

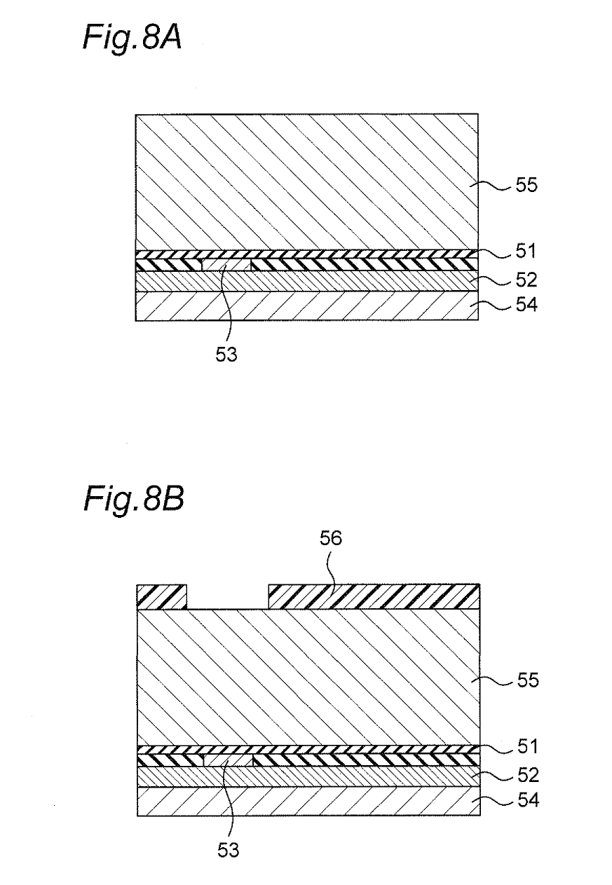

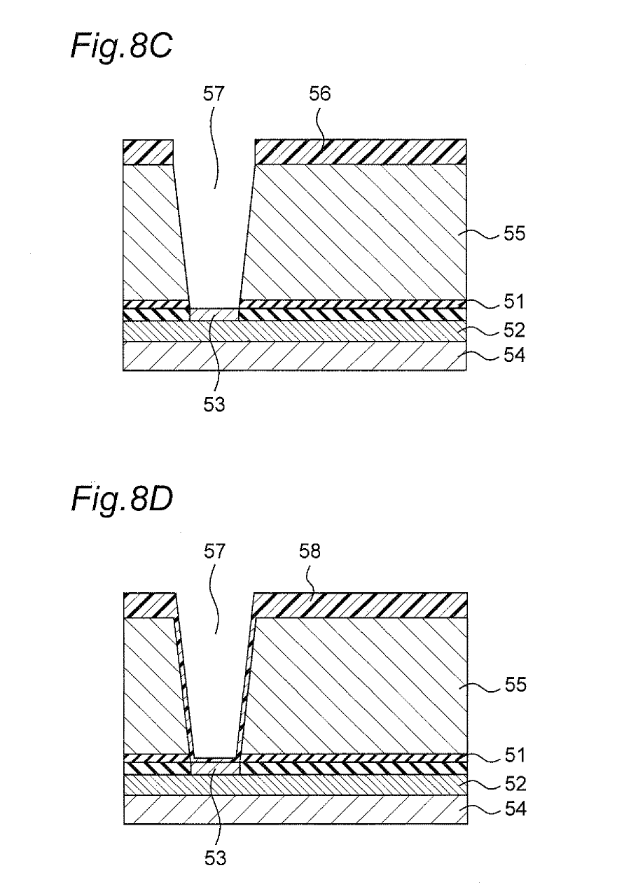

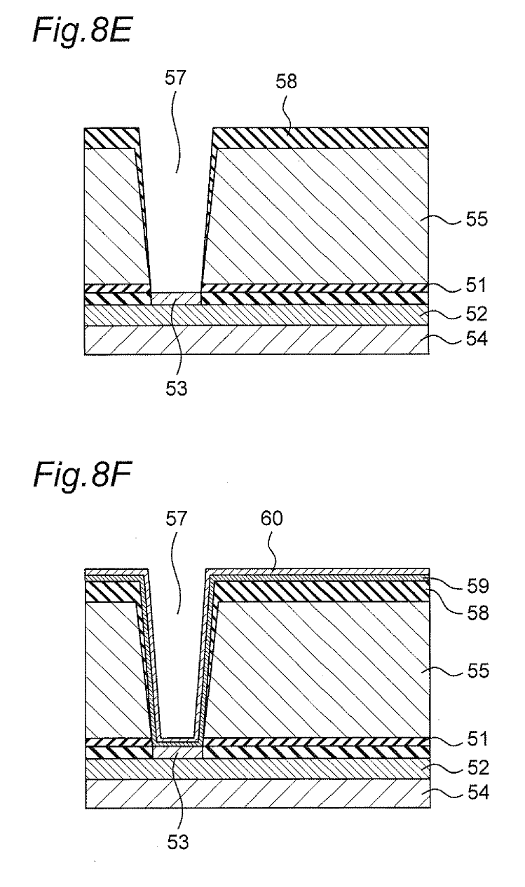

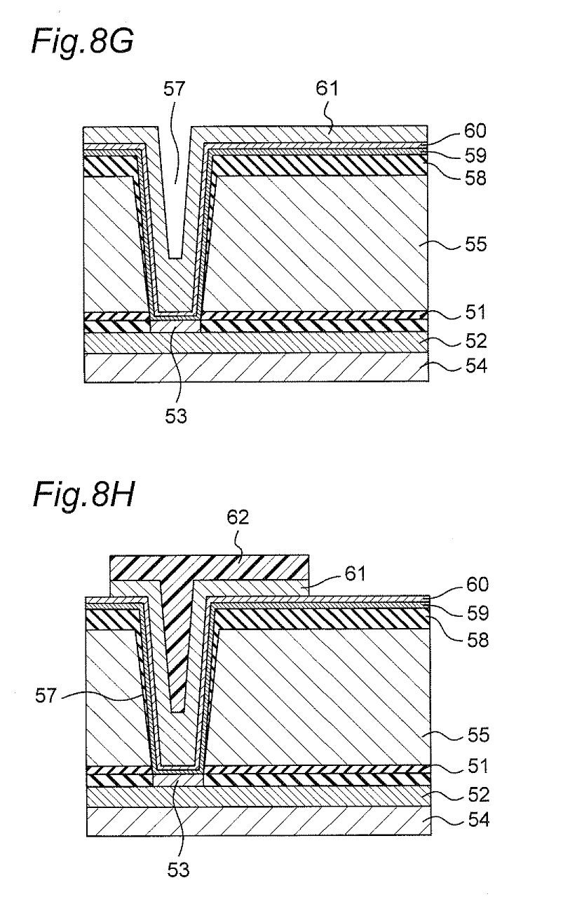

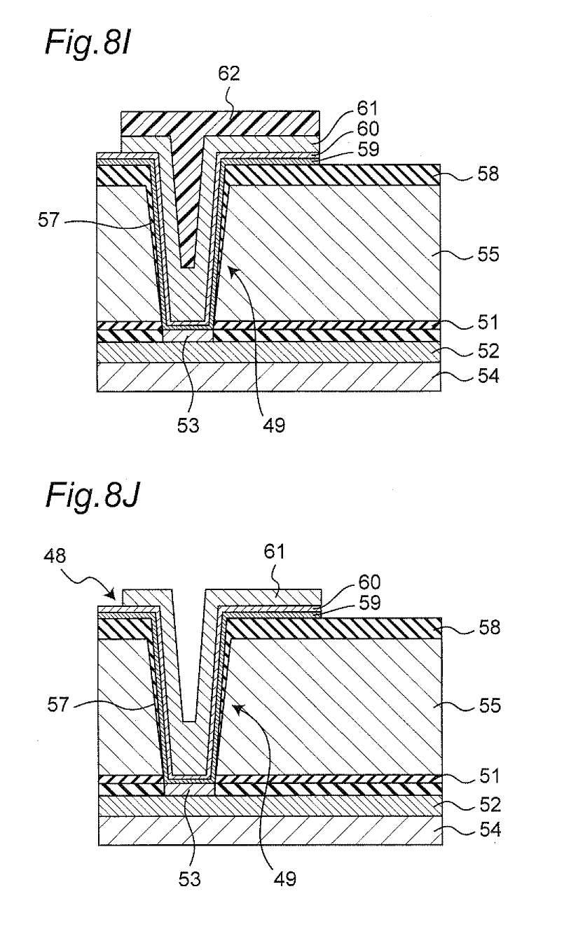

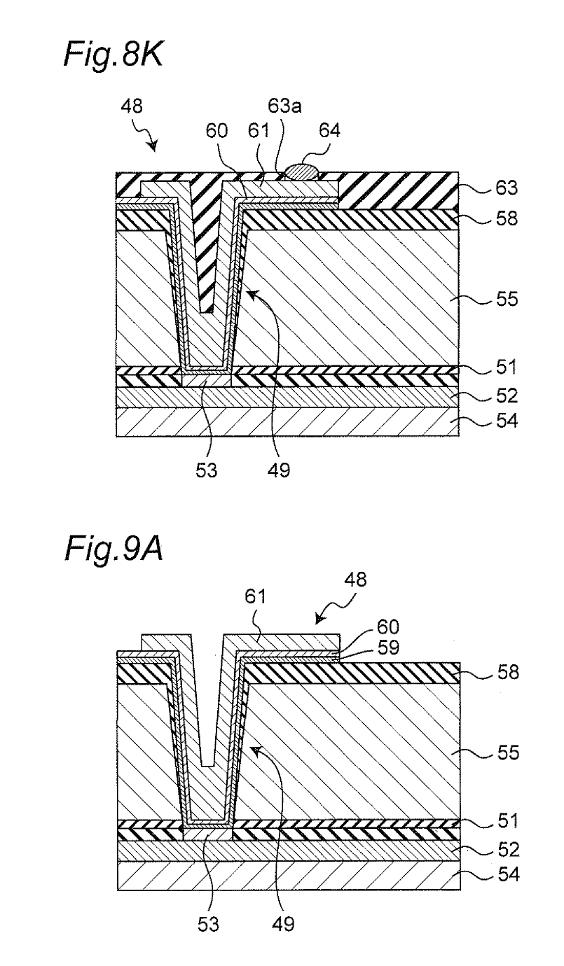

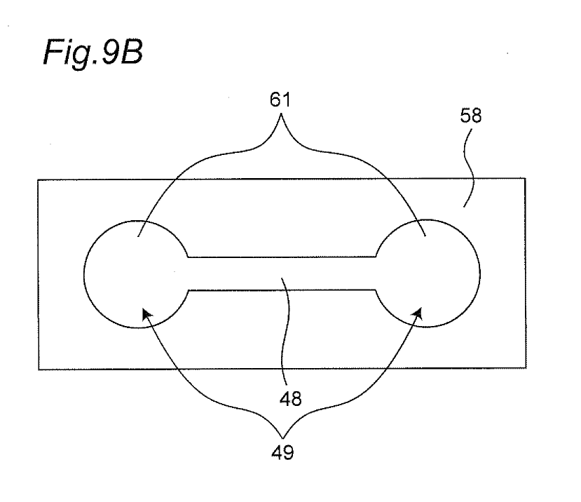

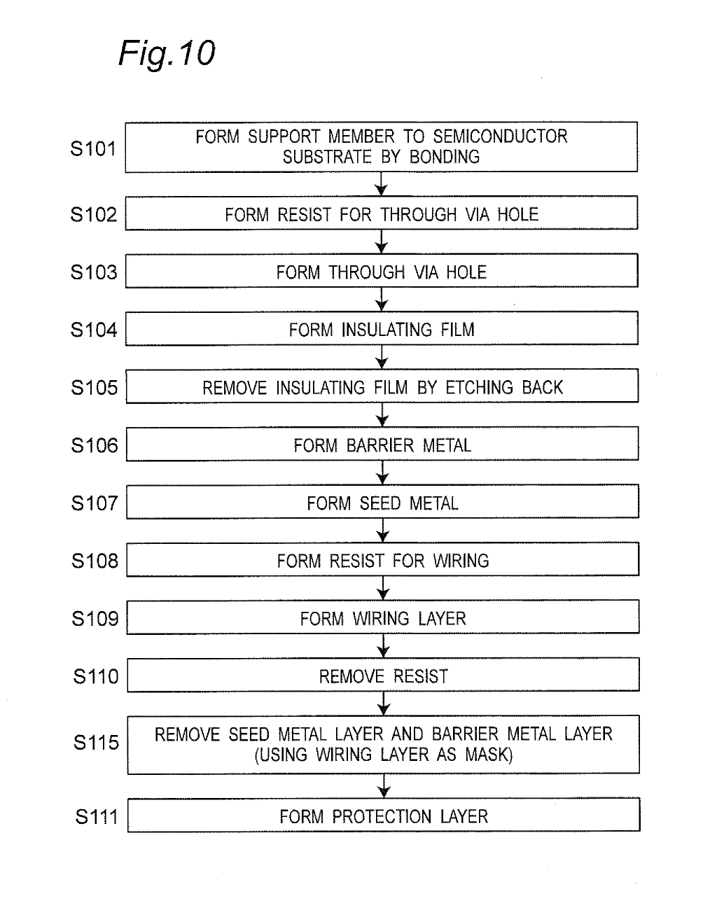

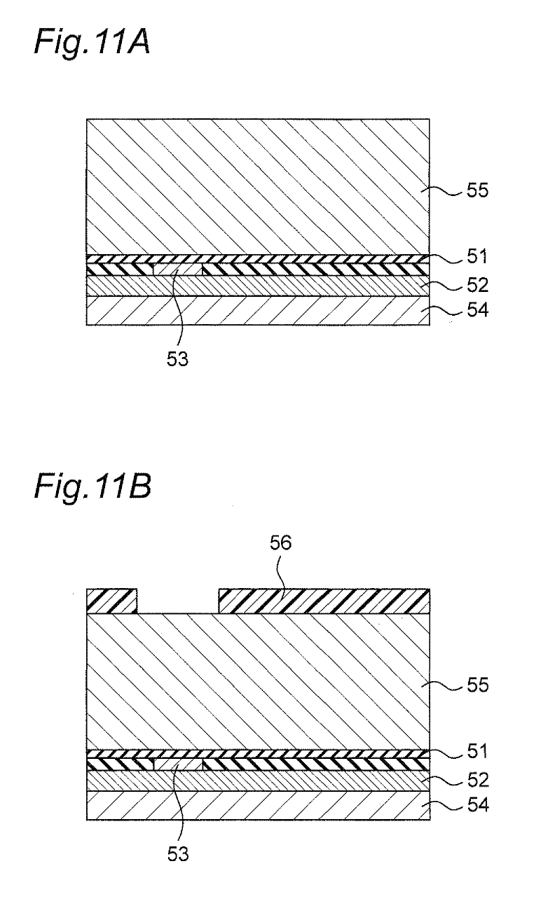

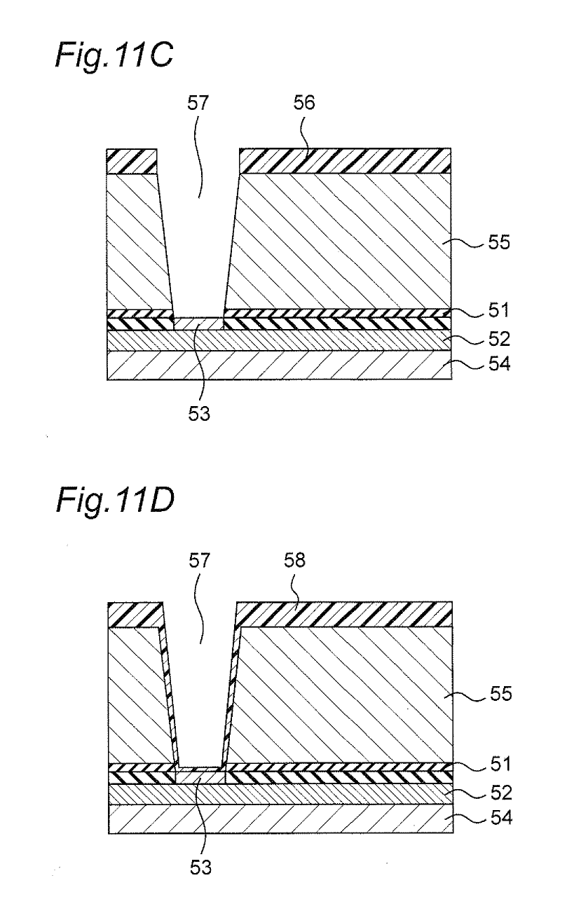

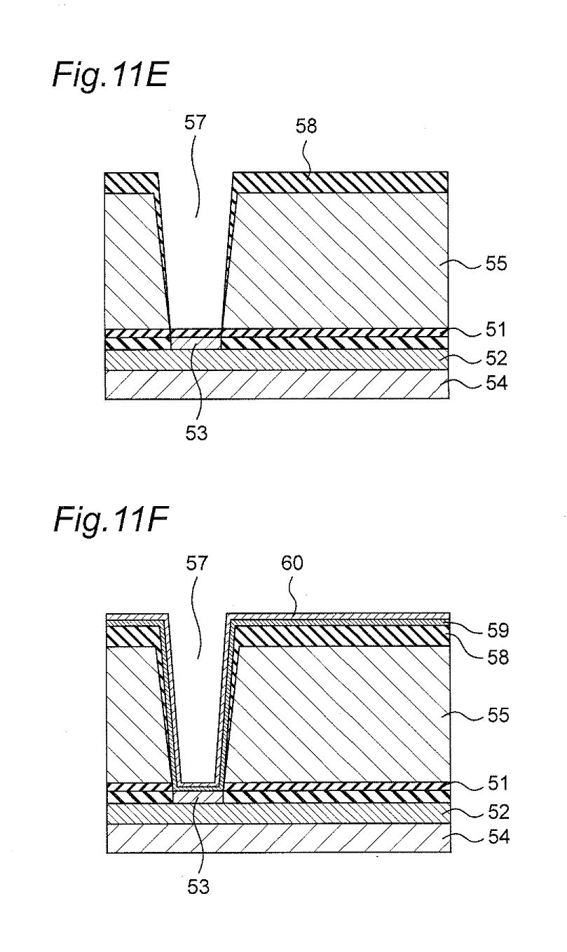

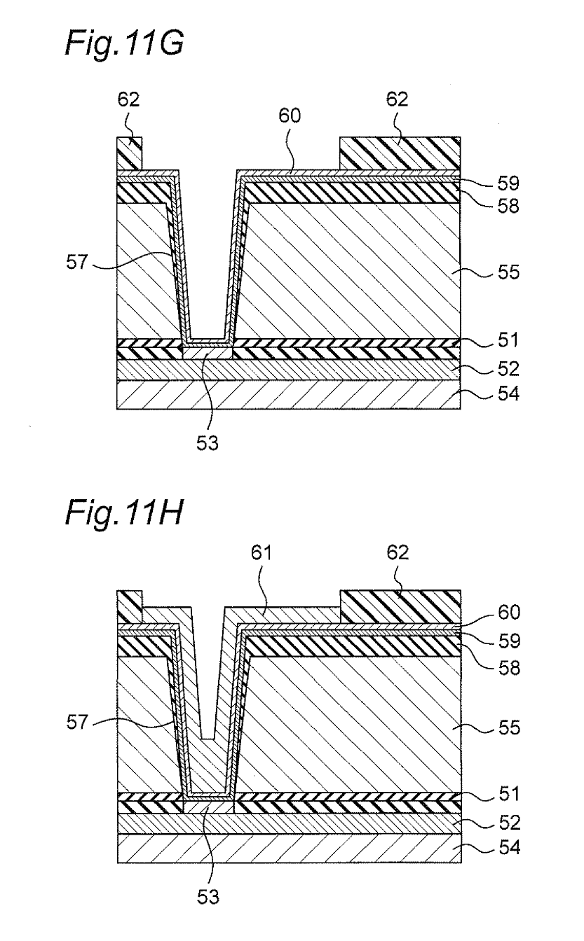

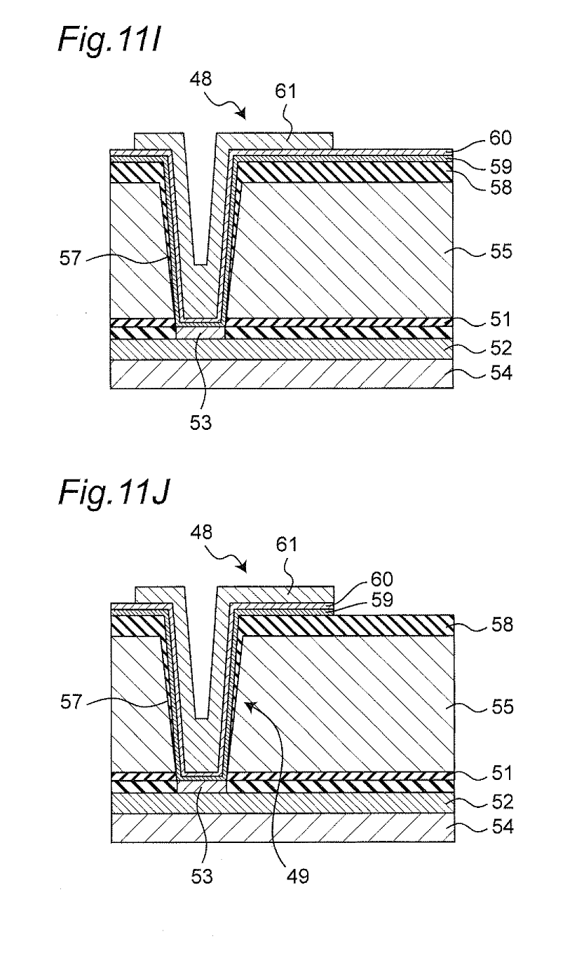

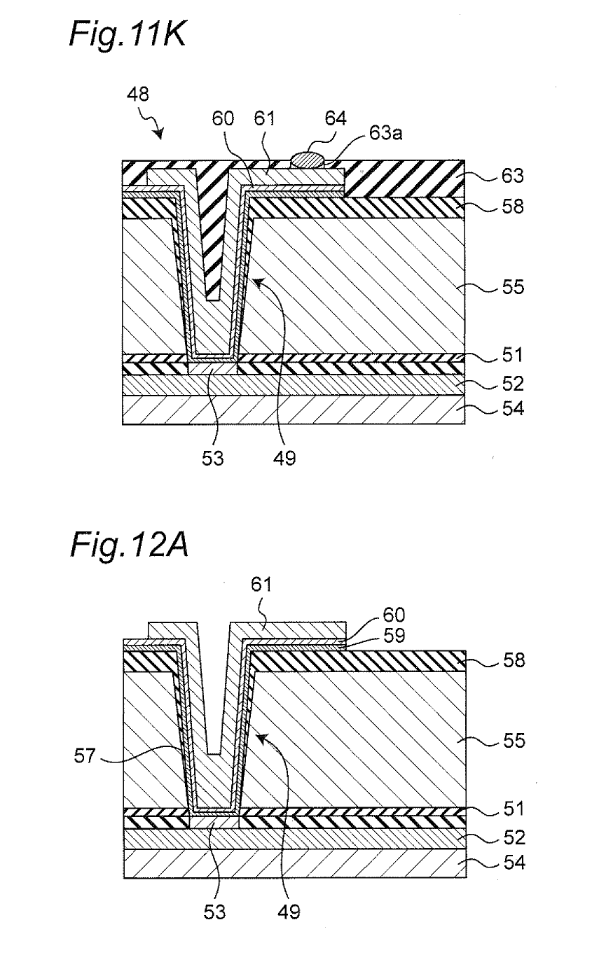

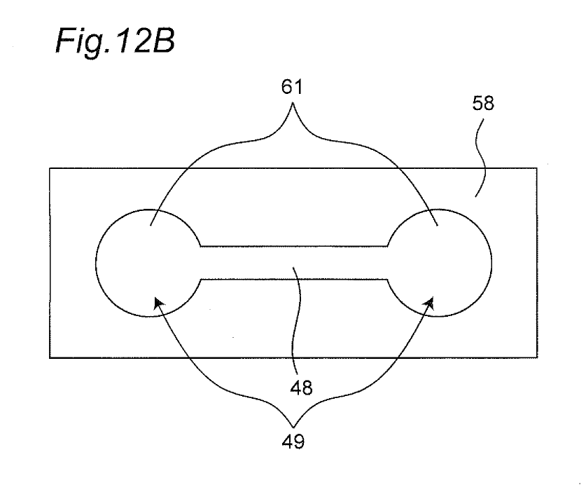

In the following, in connection with an overview of a semiconductor device manufacturing method according to the second embodiment of the present invention, a flowchart is shown in FIG. 4, and cross-sectional views at respective stages (steps) are shown in FIGS. 5A to 5L. With reference to the figures, a description will be given of the second embodiment. In connection with a semiconductor device prepared according to a manufacturing method whose description will be given later, a description will be given with reference to FIGS. 6A and 6B.

First, as shown in FIG. 5A, a support member 4 is bonded to the front surfaces (the bottom surface in FIG. 5A) of an electronic device 2 and a semiconductor substrate 5, having a first insulating film 1 and a resin layer possessing an adhesion function (not shown) interposed therebetween (step S101). Mere, the electronic device 2 is a light receiving element, such as a CCD, an infrared sensor or the like, or a light emitting element, or the like, for example. Further, on the semiconductor substrate 5, a pad electrode 3 being an external connection-purpose electrode connected to the electronic device 2 is formed. The semiconductor substrate 5 is structured with a silicon substrate, for example. The resin layer possessing an adhesion function refers to an adhesion layer. It is to be noted that the support member 4 may be bonded as necessary, and is not necessarily bonded. Further, the insulating protection layer 3A is a layer disposed to surround the pad electrode 3.

Next, as shown in FIG. 5B, on the back surface (the top surface of FIG. 55) of the semiconductor substrate 5, a through-hole electrode forming-purpose via hole 7a that penetrates through the semiconductor substrate 5 to reach the first insulating film 1 immediately above the pad electrode 3 and a frame-like insulating portion forming-purpose dummy groove hole portion (one example of the groove for forming insulating portion) 7b are formed. For this purpose, first, on the back surface (the top surface in FIG. 55) of the semiconductor substrate 5, a resist layer (a resist via pattern layer) 6 is formed (step S204). The resist layer 6 is provided with an opening 6-1 at a portion where the via hole 7a is to be formed. Further, the resist layer 6 is provided with a frame-like opening groove portion 6-2 at a portion where the dummy groove hole portion 7b is to be formed. Here, the frame-like opening groove portion 6-2 for the dummy groove hole portion 7b is set to be smaller than the resist opening 6-1 for the via hole 7a.

Next, as shown in FIG. 5C, using the resist layer 6 as a mask, and using the opening 6-1 and the frame-like opening groove portion 6-2, the hole electrode hole 7a extending from the back surface of the semiconductor substrate 5 to reach the first insulating film 1 immediately above the pad electrode 3, and the dummy groove hole portion 7b are formed simultaneously by dry etching (step S205). As the etching gas, for example, a gas that contains SF₅, O₂, C₄F₈, or the like is used. At the bottom portion of the via hole 7a, the first insulating film 1 is exposed. Since the frame-like opening groove portion 6-2 of the dummy groove hole portion 7b is set to be smaller than the opening 6-1 for the via hole 7a, the dummy groove hole portion 7b will not penetrate through the semiconductor substrate 5. Subsequently, using the resist layer 6 used in performing dry etching to the via hole 7a, as a mask, and using the opening 6-1, the first insulating film 1 at the bottom portion of the via hole 7a is removed by dry etching. As the etching gas, for example, a gas that contains CF₄, O₂, C₄F₈, or the like is used. Thus, at the bottom portion of the via hole 7a, the pad electrode 3 is partially exposed. Thereafter, the resist layer 6 is removed from the back surface of the semiconductor substrate 5.

Next, as shown in FIG. 50, on the back surface of the semiconductor substrate 5 including the insides of the via hole 7a and the dummy groove hole portion 7b, a second insulating film 8 is formed (step S104). Here, the thickness of the second insulating film 8 at the bottom portion of the via hole 7a becomes thinner than the thickness of the second insulating film 8 formed at the back surface of the semiconductor substrate 5 in accordance with the depth of the via hole 7a. Similarly, the thickness of the second insulating film 8 at the bottom portion of the dummy groove hole portion 7b also becomes thinner than the thickness of the second insulating film 8 formed on the back surface of the semiconductor substrate 5 in accordance with the depth of the dummy groove hole portion 7b.

Next, as shown in FIG. 5E, to the semiconductor substrate 5 provided with the second insulating film 8, the second insulating film 8 is etched preferably by anisotropic dry etching (step S105). By this etching, at the bottom portion of the via hole 7a and at the bottom portion of the dummy groove hole portion 7b, the second insulating film 8 is removed to partially expose the pad electrode 3. However, at the back surface of the semiconductor substrate 5, the side inner wall of the via hole 7a, and the side inner wall of the dummy groove hole portion 7b, the second insulating film 8 remains.

Next, as shown in FIG. 5F, a conductive barrier metal layer 9 is formed on the entire surface of the second insulating film 8 including: the side inner wall of the via hole 7a; the side inner wall and the bottom surface of the dummy groove hole portion 7b; and the back surface of the semiconductor substrate 5, and the part of the pad electrode 3 exposed at the bottom portion of the via hole 7a (step S106). Here, the barrier metal layer 9 is formed with a metal layer of, e.g., a titanium tungsten layer, a titanium nitride layer, a tantalum nitride layer, or the like. Further, the barrier metal layer 9 is formed by a film growth method such as sputtering, CVD, or the like.

Next, as shown in FIG. 5G, a conductive seed metal layer 10 is formed on the entire surface of the barrier metal layer 9 including: the side inner wall of the via hole 7a; the side inner wall and the bottom surface of the dummy groove hole portion 7b; the back surface of the semiconductor substrate 5, and on the entire surface of the barrier metal layer 9 on the part of the pad electrode 3 exposed at the bottom portion of the via hole 7a (step S107). The seed metal layer 10 is to be an electrode to form a wiring formation layer, whose description will be given later, by plating, and is structured with metal such as copper or the like, for example.

Next, as shown in FIG. 5H, a second resist layer 12 is formed at a prescribed region on the seed metal layer 10 (step S108). Here, the prescribed region where the second resist layer 12 is formed is a region except for a formation region of the via hole 7a. Further, the prescribed region where the second resist layer 12 is formed is a region on the back surface of the semiconductor substrate 5 where a wiring layer 18 having a prescribed pattern, whose description will be given later, is not formed. The second resist layer 12 is formed to entirely bury the inside of the dummy groove hole portion 7b.

Next, as shown in FIG. 5I, using the second resist layer 12 as a mask, a wiring formation layer 11 is formed at the side inner wall and the bottom surface of the via hole 7a, and a region on the back surface of the semiconductor substrate 5 where the wiring layer 18 is to be formed (step S109). The wiring formation layer 11 is a metal layer structured with, e.g., copper, by the electrolytic plating process, for example.

Next, as shown in FIG. 5J, the second resist layer 12 is removed (step S110). For removing the second resist layer 12, the ashing process is used, for example.

Next, as shown in FIG. 5K, using the wiring formation layer 11 as a mask, the seed metal layer 10 and the barrier metal layer 9 at the bottom portion of the dummy groove hole portion 7b are removed (step S203). Patterning carried out by the removal of the seed metal layer 10 and the barrier metal layer 9 is carried out by wet etching, for example. Here, the thickness of the seed metal layer 10 not covered by the wiring formation layer 11, the seed metal layer 10 at other portions such as at the back surface of the semiconductor substrate 5 and at the inner sidewall of the dummy groove hole portion 7b, somewhat becomes thinner. Here, the seed metal layer 10 and the barrier metal layer 9 removed by wet etching may be just those at the bottom portion of the dummy groove hole portion 7b. That is, the seed metal layer 10 and the barrier metal layer 9 on the back surface of the semiconductor substrate 5 may remain.

Next, as shown in FIG. 5L, a protection layer 13 is formed on the entire back surface of the semiconductor substrate 5 including the inside of the via hole 7a and the inside of the dummy groove hole portion 7b, so as to cover them (step S111). Here, the entire back surface of the semiconductor substrate 5 refers to the top of the seed metal layer 10 and the wiring formation layer 11 and the like, i.e., the top of the through-hole electrode 19 (a conductor portion structured with a part of the wiring formation layer 11, the seed metal layer 10, and the barrier metal layer 9) and the wiring layer 18. The protection layer 13 is structured with an insulating resist material or the like, for example. The protection layer 13 is provided with an opening 13a at the position corresponding to the wiring layer 18. Then, on the wiring layer 18 exposed at the opening 13a, a ball-like conductive terminal 14 made of metal, e.g., solder or the like, is formed. It is to be noted that, at the bottom portion of the dummy groove hole portion 7b, the insulating material of the protection layer 13 disposed in the dummy groove hole portion 7b and the material structuring the semiconductor substrate 5 are in direct contact with each other, so as to exhibit insulation. Hence, by the protection layer 13 being inserted into the dummy groove hole portion 7b such that the dummy groove hole portion 7b is filled therewith, a frame-like insulating portion 20 can be formed.

Next, along a not-shown dicing line, the semiconductor substrate 5 is subjected to dicing. Thus, a plurality of semiconductor devices each being a semiconductor chip having the through-hole electrode 19 is completed.

FIGS. 6A and 6B each show one example of a part of the semiconductor device prepared in accordance with the manufacturing method described in the foregoing. FIGS. 6A and 6B show two through-hole electrodes 19 and the wiring layer 18 connecting between the through-hole electrodes 19, in a state before the protection film 13 is formed. FIG. 6A shows a cross-sectional structure of the through-hole electrode 19, and FIG. 6B schematically shows the structure of the two through-hole electrodes 19 and the wiring layer 18 connecting between the through-hole electrodes 19 as seen from above. In FIG. 63, the top portion of the semiconductor device is structured with the two through-hole electrodes 19, a wiring layer 18 connecting between the through-hole electrodes 19, and a frame-like insulating portion 20 intended to insulate the two through-hole electrodes 19 and the wiring portion 18a from the surrounding. The frame-like insulating portion 20 is disposed in a frame-like manner, so as to surround the two through-hole electrodes 19 and the wiring portion 18a from the surrounding while being away from them by a prescribed interval. Here, what is referred to by the disposition so as to surround the two through-hole electrodes 19 and the wiring portion 18a while being away from them by a prescribed interval is, in other words, a disposition conforming to the outer shape of the two through-hole electrodes 19 and the wiring portion 18a. By such a disposition conforming to the outer shape, even in a case where each through-hole electrode 19 is arranged at a narrow pitch, a high-density wiring can be achieved. Thus, it is more suitable for a semiconductor substrate having high-density wirings. However, the frame-like insulating portion 20 is only required to surround the two through-hole electrodes 19 and the wiring portion 18a, such that they are insulated from other through-hole electrode 19 or wiring portion 18a. Therefore, it goes without saying that the frame-like insulating portion 20 is not limited to a frame-like shape conforming to the outer shape of the two through-hole electrodes 19 and the wiring portion 18a, and it may be a simple quadrilateral shape, an oval shape or the like.

The wiring layer 18 is formed to structure the wiring portion 18a that functions as a rewiring layer electrically connecting a plurality of through-hole electrodes 19 to one another, for example. It is to be noted that, as it is for FIG. 3C, the wiring layer 18 may be structured to further include external terminals 18b, and second wiring portions 18c connecting between the external terminals 18b and the through-hole electrode 19 or the wiring portion 11a.

In accordance with such a semiconductor device manufacturing method, for insulating the through-hole electrode 19 and the wiring layer 18 from other wirings, removal of the seed metal layer 10 and the barrier metal layer 9 at the bottom portion of the frame-like dummy groove hole portion 7b will suffice, and removal of the conductive layer (the seed metal layer 10 and the barrier metal layer 9) at other portions such as the side inner wall of the dummy groove hole portion 7b is not necessary. Accordingly, the present invention requires drastically shortened wet etching time which is 1/10 to ⅕ (i.e., 2 to 6 minutes) as compared with that (20 to 30 minutes) disclosed in Conventional Example 2. It is to be noted that, of Conventional Examples 1 and 2, Conventional Example 2 is an example that is advantageous in terms of the processing time of the wet etching step of the wiring formation layer 11, the seed metal layer 10, and the barrier metal layer 9. Accordingly, it becomes possible to provide a semiconductor device and a manufacturing method thereof that can drastically reduce the processing time and processing cost for the wet etching step of the wiring formation layer 11, the seed metal layer 10, and the barrier metal layer 9.

Further, as described in the foregoing, since the wet etching time is shortened, a great reduction in the thinning of the wiring formation layer 11 when the seed metal layer 10 and the barrier metal layer 9 are subjected to wet etching can be achieved, and a drastic reduction in the variation of the electric characteristic can be achieved. Accordingly, a semiconductor device and a manufacturing method thereof being high in the reliability of the electric characteristic can be provided.

Further, since the dummy groove hole portion 7b can be formed simultaneously with the formation step of the through-hole electrode-purpose via hole 7a, an increase in the processing time and processing cost due to an increase in the number of steps will not occur in the dummy groove hole portion 7b.

Further, preferably, as shown in FIG. 6C, when it is defined that the through hole diameter of the opening (the opening on the back surface of the semiconductor substrate 5) of the via hole 7a forming the through-hole electrode 19 is φ₁; and the groove width of the opening (the opening on the back surface of the semiconductor substrate 5) of the dummy groove hole portion 7b insulating between the wirings is L₂, it is desirable that the dummy groove hole portion 7b is formed such that the through hole diameter φ₁ and the groove width L₂ satisfy the following relational expression:

0<L₂<φ₁/2

This is because, when the width L₂ of the dummy groove hole portion 7b exceeds φ₁/2, the dummy groove hole portion 7b may penetrate through the semiconductor substrate 5. Another reason for that is to set the width L₂ of the dummy groove hole portion 7b to assume a value greater than 0, because it is essential to form the dummy groove hole portion 7b.

It is to be noted that, any appropriate combination of the various embodiments or variations described above can achieve their respective effects.

Although the present invention has been fully described in connection with the preferred embodiments thereof with reference to the accompanying drawings, it is to be noted that various changes and modifications are apparent to those skilled in the art. Such changes and modifications are to be understood as included within the scope of the present invention as defined by the appended claims unless they depart therefrom.

### INDUSTRIAL APPLICABILITY

The semiconductor device and the manufacturing method thereof of the present invention can reduce the processing time. Therefore, in particular, it is useful as a semiconductor device having a through-hole electrode and a manufacturing method thereof, e.g., a BGA-type semiconductor device having a through-hole electrode being one type of CSP, and a manufacturing method thereof.

1-8. (canceled)

9. A semiconductor device, comprising:
an electronic device formed on a front surface of a semiconductor substrate;
a pad electrode being established an electric conduction with the electronic device;
a through-hole electrode that penetrates through the semiconductor substrate in a thickness direction thereof;
a wiring layer formed on a back surface of the semiconductor substrate to connect between the through-hole electrodes;
a conductive terminal connected to the wiring layer or the through-hole electrode; and
a groove for forming insulating portion formed to surround the through-hole electrode and the wiring layer on the back surface of the semiconductor substrate,
wherein a bottom portion of the groove for forming insulating portion is positioned at an intermediate portion in a thickness direction from the front surface of the semiconductor substrate to the back surface of the semiconductor substrate.

10. The semiconductor device according to claim 9, wherein
the groove for forming insulating portion satisfies a relational expression of 0<L₂<φ₁/2, where φ₁ is a through hole diameter of an opening of a via hole forming the through-hole electrode on the back surface of the semiconductor substrate, and L₂ is a width of an opening of the groove for forming insulating portion on the back surface of the semiconductor substrate.

11. A semiconductor device, comprising:
an electronic device formed on a front surface of a semiconductor substrate;
a pad electrode being established an electric conduction with the electronic device;
a through-hole electrode that penetrates through the semiconductor substrate in a thickness direction thereof;
a wiring layer formed on a back surface of the semiconductor substrate to connect between the through-hole electrodes;
a conductive terminal connected to the wiring layer or the through-hole electrode; and
a groove for forming insulating portion formed to surround the through-hole electrode and the wiring layer on the back surface of the semiconductor substrate,
wherein at a bottom portion of the groove for forming insulating portion, an insulating material of an insulating layer disposed in the groove for forming insulating portion and a constituent material of the semiconductor substrate are in direct contact with each other.

12. A semiconductor device manufacturing method, comprising: forming a through-hole electrode that penetrates through a semiconductor substrate having an electronic device and a pad electrode disposed on its front surface from a back surface of the semiconductor substrate in a thickness direction thereof to establish an electric conduction with the pad electrode on the front surface of the semiconductor substrate; and forming a wiring layer that establishes an electric conduction with the through-hole electrode and that is disposed on the back surface of the semiconductor substrate, the method comprising:
forming a via hole for the through-hole electrode extending from the back surface of the semiconductor substrate in the thickness direction of the semiconductor substrate; and
forming a groove for forming insulating portion so as to surround the through-hole electrode and the wiring layer, before forming an insulating portion in the via hole,
the method further comprising, after forming the groove portion: forming a conductive layer in the groove for forming insulating portion; and removing the conductive layer at a bottom portion of the groove for forming insulating portion, and inserting an insulating material to form an insulating portion.

13. The semiconductor device manufacturing method according to claim 12, wherein
forming the via hole and forming the groove portion are simultaneously performed.

14. The semiconductor device manufacturing method according to claim 12, wherein
in forming the groove portion, the groove for forming insulating portion is formed to satisfy a relational expression of 0<L₂<φ₁/2, where φ₁ is a through hole diameter of an opening of the via hole for the through-hole electrode on the back surface of the semiconductor substrate, and L₂ is a width of an opening of the groove for forming insulating portion.
